(19) United States
(12) Patent Application Publication
(10) Pub. No.: US 2013/0221403 A1
(43) Pub. Date: Aug. 29, 2013

(54) SEMICONDUCTOR DEVICE AND METHOD OF MANUFACTURING SEMICONDUCTOR DEVICE

(71) Applicant: Fuji Electric Co., Ltd., (US)

(72) Inventor: Hong-fei LU, Matsumoto (JP)

(73) Assignee: FUJI ELECTRIC CO., LTD., Kawasaki (JP)

(21) Appl. No.: 13/859,423

(22) Filed: Apr. 9, 2013

Related U.S. Application Data
(63) Continuation of application No. PCT/JP2011/076585, filed on Nov. 17, 2011.

(51) Int. Cl. H01L 29/78; H01L 29/739

(52) U.S. Cl. CPC H01L 29/7827; H01L 29/7395
USPC 257/139; 438/137

(57) ABSTRACT

A semiconductor device and related method of manufacturing a semiconductor device that has an active region in the inner circumference of a chip with a thickness less than that of the outer circumference of the chip in which a termination structure is provided. An n field stop region, a p collector region, and a collector electrode are on the other main surface of an n⁻ drift region. The n field stop region, the p collector region, and the collector electrode extend from the active region to the termination structure. In the termination structure, a silicon oxide film has a position from a first main surface of the n⁻ drift region in a first depth direction substantially the same as the position of the collector electrode from the first main surface of the n⁻ drift region (2) in the first depth direction in the active region.

### CROSS-REFERENCE TO RELATED APPLICATIONS

This application is a continuation application, filed under 35 U.S.C. §111(a), of International Application PCT/JP2011/076585 filed on Nov. 17, 2011, at the Japanese Intellectual Property Office, the disclosure of which is incorporated herein by reference.

### BACKGROUND

1. Field

Embodiments of the present invention relate to a semiconductor device and a method of manufacturing a semiconductor device.

2. Description of the Related Art

Discrete power devices with a high breakdown voltage play a central role in power conversion devices. For example, an insulated gate bipolar transistor (IGBT) or an insulated gate field effect transistor (MOSFET: Metal Oxide Semiconductor Field Effect Transistor) having a metal-oxide-semiconductor structure has been known as an element which is suitable for the discrete power device with a high breakdown voltage which is used in the power conversion device.

In the power conversion device for a high voltage, an IGBT capable of reducing an on voltage using conductivity modulation has been generally used. Therefore, in order to reduce the loss of the power conversion device, it is important to reduce the conduction loss and switching loss of the IGBT used in the power conversion device. The cross-sectional structure of the IGBT according to the related art will be described using, for example, an IGBT with the planar structure illustrated in FIG. 34. FIG. 34 is a cross-sectional view illustrating the structure of the IGBT according to the related art.

In the IGBT according to the related art illustrated in FIG. 34, an n buffer layer 104 and an n⁻ drift region 102 are provided on one main surface (hereinafter, referred to as a front surface) of a p⁺ semiconductor substrate 101 which is a p⁺ collector region. The resistivity of the n⁻ drift region 102 is higher than that of the n buffer layer 104. A p base region 105 is selectively provided in a surface layer (hereinafter, referred to as a front surface layer) of the n⁻ drift region 102 opposite to the p⁺ semiconductor substrate 101. An n⁺ emitter region 106 is selectively provided in the front surface layer of the p base region 105.

The resistivity of the n⁺ emitter region 106 is lower than that of the n⁻ drift region 102. A gate electrode 108 is provided on the surface of the p base region 105 interposed between the n⁺ emitter region 106 and the n⁻ drift region 102, with a gate insulating film 107 interposed therebetween. An emitter electrode 109 comes into contact with the n⁺ emitter region 106 and the p base region 105. The emitter electrode 109 is insulated from the gate electrode 108 by an interlayer insulating film (not illustrated). A collector electrode (not illustrated) comes into contact with the other main surface (hereinafter, referred to as a rear surface) of the p⁺ semiconductor substrate 101.

In recent years, a technique for thinning the wafer has been developed and applied to the IGBT according to the related art. When the technique for thinning the wafer is used to manufacture (fabricate) the IGBT according to the related art having a structure illustrated in FIG. 34, for example, the p⁺ semiconductor substrate 101 which is a p⁺ collector region is not used, but a semiconductor wafer (hereinafter, referred to as an FZ wafer) which is the n⁻ drift region 102 and is manufactured by a floating zone (FZ) method is used. As a method of manufacturing the IGBT according to the related art using the FZ wafer, for example, the following method is mainly used.

First, a surface element structure including, for example, the p base region 105, the n⁺ emitter region 106, the gate insulating film 107, and the gate electrode 108 is formed on the front surface of the FZ wafer which is the n⁻ drift region 102. Then, the FZ wafer is thinned from the rear surface of the FZ wafer. Then, the n buffer layer 104 and the p⁺ collector region (not illustrated) are formed on a surface layer of the rear surface of the FZ wafer. In this way, the IGBT according to the related art having the structure illustrated in FIG. 34 is completed. As such, when the IGBT is manufactured using the FZ wafer, the thickness of the p⁺ collector region is equal to or less than 2 μm, but the function of a support for maintaining the mechanical strength of the IGBT is removed from the p⁺ collector region.

In addition to the above-mentioned IGBT according to the related art, a reverse blocking IGBT (RB-IGBT) in which a termination structure for maintaining a reverse breakdown voltage is provided in a pn junction including a collector region and a drift region has been known as the IGBT according to the related art. The RB-IGBT has high reverse breakdown voltage characteristics for a reverse bias voltage applied to the pn junction including the collector region and the drift region. Next, the cross-sectional structure of the RB-IGBT according to the related art will be described. FIG. 35 is a cross-sectional view illustrating the structure of the RB-IGBT according to the related art.

In the RB-IGBT illustrated in FIG. 35, a p collector region 111 is provided on the entire rear surface of a semiconductor wafer which is an n⁻ drift region 102. A collector electrode 112 comes into contact with the p collector region 111. A p isolation region 124 is provided so as to extend from the front surface of the semiconductor wafer which is the n⁻ drift region 102 to the p collector region 111. A plurality of floating p regions (field limiting rings) 114 are provided in a surface layer of the front surface of the n⁻ drift region 102.

A plurality of floating region (hereinafter, referred to as field plate regions) 117 made of polysilicon are provided on the front surface of the n⁻ drift region 102. Each field plate region 117 comes into contact with a high-concentration p⁺ region which is provided in the front surface layer of each field limiting ring 114. A field plate 118 which is provided in the outermost circumference of the front surface of the n⁻ drift region 102 comes into contact with the high-concentration p⁺ region which is provided in the front surface layer of a p isolation region 124. Each field plate region 117 and the field plate 118 are insulated from each other by an interlayer insulating film.

The field limiting rings 114 and the field plate regions 117 form the termination structure. The p isolation region 124 surrounds the termination structure and the termination structure surrounds the active region. When the semiconductor device is turned on, a current flows in the active region. In the active region, similarly to the IGBT illustrated in FIG. 34, a p base region 105, an n⁺ emitter region 106, a gate insulating film 107, a gate electrode 108, an emitter electrode 109, and an interlayer insulating film 116 which insulates the gate electrode 108 from the emitter electrode 109 are provided on the front surface of the n⁻ drift region 102.

A p⁺ base contact region 110 which comes into contact with the n⁺ emitter region 106 is provided in the surface layer of the p base region 105. The n⁺ emitter region 106 and the p⁺ base contact region 110 are electrically connected to each other by the emitter electrode 109. An n hole barrier region 113 is provided in a surface layer of the front surface of the n⁻ drift region 102 so as to cover the surface of the p base region 105 close to the p collector region 111. The resistivity of the n hole barrier region 113 is lower than that of the n⁻ drift region 102.

In the IGBT and the RB-IGBT according to the related art respectively illustrated in FIGS. 34 and 35, it has been known that a reduction in the thickness of the n⁻ drift region 102 is effective in reducing conduction loss and switching loss. In addition, in recent years, as the IGBT according to the related art which is manufactured using the wafer which is the n⁻ drift region 102, a field stop IGBT has been mainly used in which the n-type impurity concentration of the n buffer layer 104 provided in a surface layer of the rear surface of the n⁻ drift region 102 is optimized to set the thickness of the n⁻ drift region 102 to a minimum value required to obtain the desired breakdown voltage of the element.

When the wafer is thinned, the limit value (hereinafter, referred to as a limit thickness) of the thickness of the wafer is about 80 μm in terms of manufacturability, which also depends on a manufacturing apparatus or a manufacturing method. The reason is that, when the thickness of the wafer is thinned to be equal to or less than 80 μm, mechanical strength is reduced and yield is significantly reduced. The breakdown voltage of the element depends on the thickness of the n⁻ drift region 102. Therefore, as the breakdown voltage is reduced, the design thickness of the n⁻ drift region 102 in the IGBT is reduced. As described above, since the wafer has the limit thickness in terms of manufacturability, in general, the thickness of the n⁻ drift region 102 in the IGBT with a breakdown voltage class of 600 V or less is equal to or greater than a design thickness required for obtaining a desired breakdown voltage. Therefore, in the IGBT with a breakdown voltage class of 600 V or less, it is possible to greatly improve the performance by reducing the thickness of the wafer.

For example, the IGBT with a breakdown voltage class of 600 V or less is used for the following various purposes. An IGBT with a breakdown voltage class of 400 V is widely used in a pulsed power supply for a plasma display panel (PDP) or a strobe. In addition, when an input voltage to a power conversion device is 220 V (AC: alternating current), a DC (direct current) link voltage after rectification is 300 V. Therefore, an IGBT with a breakdown voltage class of 600 V is used in a main element of an inverter of the power conversion device.

In addition, a technique has been proposed in which the output voltage level control of an inverter of a power conversion device is changed from two-level control according to the related art to three-level control to improve the power conversion efficiency of the power conversion device (for example, see the following Non-patent Literature 1 (FIG. 10)). When the output voltage level control of the inverter of the power conversion device is three-level control, an IGBT with a breakdown voltage class of 400 V is used in an intermediate switching element of a three-level conversion unit which converts the output voltage from the inverter into three levels. In addition, a technique has been proposed in which an RB-IGBT with a breakdown voltage class of 400 V having the same function as that in the related art in which an IGBT and a diode are connected in series to each other is used in an intermediate switching element of a three-level conversion unit (for example, see the following Non-patent Literature 2 (FIG. 1)).

In an electric vehicle (EV), since power is supplied from a driving battery to a motor, which is a driving source, through a power conversion device, it is important to improve the power conversion efficiency of the power conversion device. When a power of 80 kW or less is supplied from the driving battery to the motor, it is appropriate that the DC link voltage of the power conversion device is in the range of about 100 V to 250 V. Therefore, an IGBT with a breakdown voltage class of 400 V is used in the main element of the inverter of the power conversion device.

In the IGBT, the design thickness of the n⁻ drift region 102 required to obtain a breakdown voltage class of 400 V is about 40 μm which is less than the limit thickness of the wafer. Therefore, when the thickness of the n⁻ drift region 102 in the IGBT is about 40 μm, it is difficult to ensure the mechanical strength of the wafer. When the IGBT with a breakdown voltage class of 400 V is manufactured, it is difficult to reduce the thickness of the n⁻ drift region 102 to 40 μm which is a design thickness required to obtain a breakdown voltage class of 400 V.

As a method of ensuring the mechanical strength of a thin wafer, the following method has been proposed. FIGS. 36 and 37 are cross-sectional views illustrating the cross-sectional structure of a semiconductor device according to the related art which is being manufactured. First, as illustrated in FIG. 36, a protective resist film 211 covers the front surface of a wafer 200 on which a surface element structure 201 is formed. Then, a back grind (BG) tape 212 is attached to the front surface of the wafer 200 covered with the protective resist film 211. Then, as illustrated in FIG. 37, only a central portion 200-2 of the rear surface of the wafer 200 is polished and thinned such that a portion (hereinafter, referred to as a rib portion) 200-1 which is a few millimeters inside the outer circumferential end of the wafer 200 remains. When the wafer 200 is thinned in this way, the concentration of stress on the rib portion 200-1 of the wafer 200 is prevented, as compared to a case in which the entire rear surface of the wafer 200 is uniformly polished, and the mechanical strength of the wafer 200 is improved. Therefore, the warping of the wafer 200 is reduced and, for example, chipping or breaking is reduced (see the following Non-patent Document 3).

As another method for ensuring the mechanical strength of a thin wafer, the following method has been proposed. FIG. 38 is a cross-sectional view illustrating the cross-sectional structure of the semiconductor device according to the related art which is being manufactured. First, as illustrated in FIG. 38, an oxide film 221, which is an etching-resistant protective film, covers the front surface of a wafer 200 on which a surface element structure 201 is formed and the rear surface thereof. Then, a resist mask 222 is formed on the rear surface of the wafer 200 so as to cover a portion of the oxide film 221 with a predetermined width from the outer circumferential end of the wafer 200 to the inner circumferential side. Then, the oxide film 221 on the rear surface of the wafer 200 is removed using a resist mask 222 such that the portion of the oxide film 221 with a predetermined width from the outer circumferential end of the wafer 200 to the inner circumferential side remains on the rear surface of the wafer 200. Then, etching is performed using the oxide film 221 as a mask to remove the rear surface of the wafer 200 to a predetermined depth. In this way, a rib portion is formed in the outer circumference of the wafer 200. Then, the oxide film 221 remaining on the front and rear surfaces of the wafer 200 is removed (for example, see the following Patent Document 1).

### RELATED ART PATENT DOCUMENTS

Patent Document 1: JP 2007-335659 A

### RELATED ART NON-PATENT DOCUMENTS

Non-Patent Document 1: A. Naeba et al., “A New Neutral-Point-Clamped PWM Inverter,” IEEE Transactions on Industry Applications, 1981, Vol. 1A to 17, No. 5, p. 518-523

Non-Patent Document 2: M. Yatsu et al., “A Study of High Efficiency UPS Using Advanced Three-level Topology,” Preliminary Conference Program PCIM Europe 2010, (Nuremberg), May 2010, pp. 550-555
Non-Patent Document 3: DISCO Corporation, “TAIKO Process”, [online], 2001 to 2011, Internet, [Searched Oct. 28, 2011], <URL: http://www.disco.co.jp/jp/solution/library/taiko.html>

However, in the techniques according to the related art illustrated in FIGS. 36 to 38, the wafer 200 is reinforced only by the rib portion 200-1 provided in the outer circumference of the wafer 200. Therefore, as the thickness of the central portion 200-2 of the wafer 200 is reduced and the diameter of the wafer 200 increases, the mechanical strength of the wafer 200 is reduced. In this case, the wafer 200 is likely to be broken. Therefore, as described above, it is difficult to reduce the thickness of the wafer 200 to be equal to or less than 80 μm, which is a limit thickness at which the above-mentioned problem does not occur, in terms of manufacturability.

In the wafer 200 which is thinned by the related art illustrated in FIGS. 36 to 38 described above, in the electrical characteristic test for the wafer 200 before the wafer 200 having a plurality of elements provided therein is diced into individual chips, for example, the collector electrode on the rear surface of the wafer 200 directly contacts a support on which the wafer 200 is placed. Therefore, in the IGBT according to the related art, there is a concern that the p collector region 111 or the n buffer layer 104 will be damaged due to, for example, materials (particles) attached to the rear surface of the wafer 200 or friction, resulting in a reduction in breakdown voltage or an increase in leakage current. In addition, in the RB-IGBT according to the related art, there is a concern that the p collector region 111 will be damaged due to, for example, materials attached to the rear surface of the wafer 200 or friction and reverse breakdown voltage characteristics will deteriorate or the reverse breakdown voltage characteristics will not be obtained.

### SUMMARY

In order to solve the problems of the related art described above, an object of embodiments of the invention is to provide a semiconductor device with high mechanical strength and a method of manufacturing the semiconductor device. In addition, in order to solve the problems of the related art, an object of embodiments of the invention is to provide a semiconductor device capable of reducing conduction loss and switching loss and a method of manufacturing the semiconductor device. Furthermore, in order to solve the problems of the related art, an object of embodiments of the invention is to provide a semiconductor device capable of improving yield and a method of manufacturing the semiconductor device.

In order to solve the above-mentioned problems and achieve objects of embodiments of the invention, a semiconductor device according to a first aspect of the invention includes: a first semiconductor region of a first conduction type; a second semiconductor region which is a second conduction type and comes into contact with one surface of the first semiconductor region; a third semiconductor region which is the second conduction type, comes into contact with a surface of the second semiconductor region opposite to the first semiconductor region, and has a resistivity higher than that of the second semiconductor region; a fourth semiconductor region which is the first conduction type and is selectively provided in a surface layer of the third semiconductor region opposite to the second semiconductor region; a fifth semiconductor region which is the second conduction type, is provided in the fourth semiconductor region, and has a resistivity lower than that of the third semiconductor region; a gate electrode which is formed on a surface of the fourth semiconductor region interposed between the third semiconductor region and the fifth semiconductor region, with a gate insulating film interposed therebetween; a first electrode which electrically connects the fourth semiconductor region and the fifth semiconductor region; a second electrode which comes into contact with the other surface of the first semiconductor region; an active region which is formed by at least the first semiconductor region, the second semiconductor region, and the third semiconductor region and is provided in the inner circumference of a chip which is thinner than the outer circumference of the chip; a termination structure which is provided closer to the outer circumference of the chip than the active region; and an insulating region which is selectively provided in the termination structure and is disposed substantially at the same position as that of the second electrode in a first depth direction from the surface of the third semiconductor region opposite to the second semiconductor region to the second semiconductor region.

In a second aspect of the invention, a semiconductor device according to embodiments of the invention may further include a sixth semiconductor region which is the second conduction type, is selectively provided in a surface layer of the third semiconductor region opposite to the second semiconductor region, and covers a surface of the fourth semiconductor region close to the second semiconductor region. The gate electrode may be provided on the surfaces of the third semiconductor region, the sixth semiconductor region, the fourth semiconductor region, and the fifth semiconductor region, with the gate insulating film interposed therebetween.

In a third aspect of the invention, a semiconductor device includes: a first semiconductor region of a first conduction type; a second semiconductor region which is a second conduction type and comes into contact with one surface of the first semiconductor region; a third semiconductor region which is the second conduction type, comes into contact with a surface of the second semiconductor region opposite to the first semiconductor region, and has a resistivity higher than that of the second semiconductor region; a fourth semiconductor region which is the first conduction type and is selectively provided in a surface layer of the third semiconductor region opposite to the second semiconductor region; a trench which reaches the third semiconductor region through the fourth semiconductor region; a gate insulating film which is provided along a side wall and a bottom of the trench; a gate electrode which is buried in the gate insulating film; a fifth semiconductor region which is the second conduction type, is provided in the fourth semiconductor region so as to come into contact with the gate insulating film on the side wall of the trench, and has a resistivity lower than that of the third semiconductor region; a first electrode which electrically connects the fourth semiconductor region and the fifth semiconductor region; a second electrode which comes into contact with the other surface of the first semiconductor region; an active region which is formed by at least the first semiconductor region, the second semiconductor region, and the third semiconductor region and is provided in the inner circumference of a chip which is thinner than the outer circumference of the chip; a termination structure which is provided closer to the outer circumference of the chip than the active region; and an insulating region which is selectively provided in the termination structure and is disposed substantially at the same position as that of the second electrode in a first depth direction from the surface of the third semiconductor region opposite to the second semiconductor region to the second semiconductor region.

In a fourth aspect of the invention, in a semiconductor device according to embodiments of the invention, the first semiconductor region and the second electrode may be provided so as to extend from the active region to the termination structure, and the position of the insulating region from the surface of the third semiconductor region opposite to the second semiconductor region in the first depth direction may be substantially the same as the position of the second electrode from the surface of the third semiconductor region opposite to the second semiconductor region in the first depth direction in the active region.

In a fifth aspect of the invention, in a semiconductor device according to embodiments of the invention, the second semiconductor region may be provided so as to extend from the active region to the termination structure, and the depth of the second semiconductor region in the first depth direction in the active region may be less than the depth of the second semiconductor region in the first depth direction in the termination structure.

In a sixth aspect of the invention, in a semiconductor device according to embodiments of the invention, the depth of the second semiconductor region in the first depth direction in the active region may be equal to or greater than 1.5 μm.

In a seventh aspect of the invention, in a semiconductor device according to embodiments of the invention, the thickness of the outer circumference of the chip in which the termination structure is provided may be greater than 80 μm.

In an eighth aspect of the invention, in a semiconductor device according to embodiments of the invention, the termination structure may include: a plurality of seventh semiconductor regions which are the first conduction type and are selectively provided in the surface layer of the third semiconductor region opposite to the second semiconductor region; a plurality of field plate regions which are electrically connected to the plurality of seventh semiconductor regions, respectively; an eighth semiconductor region which is the second conduction type, is selectively provided in a portion of the surface layer of the third semiconductor region which is opposite to the second semiconductor region and is closer to the outer circumference of the chip than the seventh semiconductor region so as to be separated from the seventh semiconductor region, and has a resistivity less than that of the third semiconductor region; and a field plate which comes into contact with the eighth semiconductor region.

In a ninth aspect of the invention, in a semiconductor device according to embodiments of the invention, the field plate region may be made of polysilicon.

In a tenth aspect of the invention, a semiconductor device includes: a first semiconductor region of a first conduction type; a third semiconductor region which is a second conduction type and comes into contact with one surface of the first semiconductor region; a fourth semiconductor region which is the first conduction type and is selectively provided in a surface layer of the third semiconductor region opposite to the first semiconductor region; a fifth semiconductor region which is the second conduction type, is provided in the fourth semiconductor region, and has a resistivity lower than that of the third semiconductor region; a gate electrode which is formed on a surface of the fourth semiconductor region interposed between the third semiconductor region and the fifth semiconductor region, with a gate insulating film interposed therebetween; a first electrode which electrically connects the fourth semiconductor region and the fifth semiconductor region; a second electrode which comes into contact with the other surface of the first semiconductor region; an active region which is formed by at least the first semiconductor region and the third semiconductor region and is provided in the inner circumference of a chip which is thinner than the outer circumference of the chip; a termination structure which is provided closer to the outer circumference of the chip than the active region; and an insulating region which is selectively provided in the termination structure and is disposed substantially at the same position as that of the second electrode in a first depth direction from the surface of the third semiconductor region opposite to the first semiconductor region to the first semiconductor region.

In an eleventh aspect of the invention, a semiconductor device according to embodiments of the invention may further include a sixth semiconductor region which is the second conduction type, is selectively provided in a surface layer of the third semiconductor region opposite to the first semiconductor region, and covers a surface of the fourth semiconductor region close to the first semiconductor region. The gate electrode may be provided on the surfaces of the third semiconductor region, the sixth semiconductor region, the fourth semiconductor region, and the fifth semiconductor region, with the gate insulating film interposed therebetween.

In a twelfth aspect of the invention, a semiconductor device includes: a first semiconductor region of a first conduction type; a third semiconductor region which is a second conduction type and comes into contact with one surface of the first semiconductor region; a fourth semiconductor region which is the first conduction type and is selectively provided in a surface layer of the third semiconductor region opposite to the first semiconductor region; a trench which reaches the third semiconductor region through the fourth semiconductor region; a gate insulating film which is provided along a side wall and a bottom of the trench; a gate electrode which is buried in the gate insulating film; a fifth semiconductor region which is the second conduction type, is provided in the fourth semiconductor region so as to come into contact with the gate insulating film on the side wall of the trench, and has a resistivity lower than that of the third semiconductor region; a first electrode which electrically connects the fourth semiconductor region and the fifth semiconductor region; a second electrode which comes into contact with the other surface of the first semiconductor region; an active region which is formed by at least the first semiconductor region and the third semiconductor region and is provided in the inner circumference of a chip which is thinner than the outer circumference of the chip; a termination structure which is provided closer to the outer circumference of the chip than the active region; and an insulating region which is selectively provided in the termination structure and is disposed substantially at the same position as that of the second electrode in a first depth direction from the surface of the third semiconductor region opposite to the first semiconductor region to the first semiconductor region.

In a thirteenth aspect of the invention, in a semiconductor device according to embodiments of the invention, the first semiconductor region and the second electrode may be provided so as to extend from the active region to the termination structure, and the position of the insulating region from the surface of the third semiconductor region opposite to the first semiconductor region in the first depth direction may be substantially the same as the position of the second electrode from the surface of the third semiconductor region opposite to the first semiconductor region in the first depth direction in the active region.

In a fourteenth aspect of the invention, a semiconductor device according to embodiments of the invention may further include a ninth semiconductor region which is the first conduction type and is provided in the third semiconductor region so as to be deeper than the first semiconductor region in a second depth direction from the other surface of the first semiconductor region to the third semiconductor region and to overlap the insulating region.

In a fifteenth aspect of the invention, in a semiconductor device according to embodiments of the invention, the thickness of the outer circumference of the chip in which the termination structure is provided may be greater than 80 μm.

In a sixteenth aspect of the invention, in a semiconductor device according to embodiments of the invention, the termination structure may include: a plurality of seventh semiconductor regions which are the first conduction type and are selectively provided in the front surface layer of the third semiconductor region opposite to the second semiconductor region; a plurality of field plate regions which are electrically connected to the plurality of seventh semiconductor regions; a tenth semiconductor region which is the first conduction type, is selectively provided in a portion of the surface layer of the third semiconductor region which is opposite to the first semiconductor region and is closer to the outer circumference of the chip than the seventh semiconductor region so as to be separated from the seventh semiconductor region, and comes into contact with the ninth semiconductor region; and a field plate which comes into contact with the tenth semiconductor region.

In a seventeenth aspect of the invention, in a semiconductor device according to embodiments of the invention, the field plate region may be made of polysilicon.

In an eighteenth aspect of the invention, there is a method of manufacturing a semiconductor device that includes an active region which is provided in the inner circumference of a chip thinner than the outer circumference of the chip. First, forming an insulating region on a main surface of a first wafer which is a first conduction type is performed. Then, forming a second-conduction-type semiconductor region in a front surface layer of a main surface of a second wafer which is a second conduction type is performed. Then, bonding the surface of the first wafer on which the insulating region is formed and the surface of the second wafer on which the second-conduction-type semiconductor region is formed is performed. Then, combining the bonded first and second wafers using a heat treatment is performed.

In a nineteenth aspect of the invention, there is a method of manufacturing a semiconductor device that includes an active region which is provided in the inner circumference of a chip thinner than the outer circumference of the chip. First, forming an insulating region on a main surface of a first wafer which is a first conduction type is performed. Then, forming a first-conduction-type semiconductor region in a surface layer on an outer circumference of the chip of a main surface of a second wafer which is a second conduction type is performed. Then, bonding the surface of the first wafer on which the insulating region is formed and the surface of the second wafer on which the first-conduction-type semiconductor region is formed is performed. Then, combining the bonded first and second wafers using a heat treatment is performed.

In a twentieth aspect of the invention, the method of manufacturing the semiconductor device according to embodiments of the invention may further include forming a surface element structure in the active region of the main surface, which is opposite to the first wafer, of the second wafer combined with the first wafer.

In a twenty-first aspect of the invention the method of manufacturing the semiconductor device according to embodiments of the invention may further include performing wet etching to selectively remove a portion corresponding to the surface element structure in the first wafer combined with the second wafer.

According to embodiments of the invention, portions (hereinafter, referred to as rib portions) with a thickness larger than the thickness of the chip in the active region can be provided in the outer circumference of each of the chips in which a plurality of elements are arranged in the wafer so as to surround the active region. Specifically, for example, the rib portions are arranged in a lattice shape along the scrub lines of the wafer. Therefore, even when the thickness of the chip in the active region is reduced to a design value required to obtain a desired breakdown voltage, the rib portions provided in the outer circumference of the chip can reduce the concentration of stress on the wafer. As a result, the wafer is less likely to be broken than the wafer according to the related art in which the rib portions are formed only in the outer circumference of the wafer.

According to embodiments of the invention, since the thickness of the chip in the active region can be reduced to the design value required to obtain a desired breakdown voltage, it is possible to improve the tradeoff relation between the conduction loss and switching loss of an element.

According to embodiments of the invention, before, for example, the surface element structure of the element is formed, the second semiconductor region is formed. Therefore, when the first wafer and the second wafer are bonded to each other and when, for example, the surface element structure of the element is formed, it is possible to thermally diffuse the second semiconductor region. Therefore, it is possible to increase the diffusion depth of the second semiconductor region, as compared to the related art in which, after an element is formed on the wafer, the wafer is thinned and the second semiconductor region is formed in the thin wafer. As a result, it is possible to reduce a leakage current which occurs due to the thin second semiconductor region in the related art.

According to embodiments of the invention, the ninth semiconductor region is formed before, for example, the surface element structure of the element is formed. Therefore, it is possible to reduce the thermal diffusion time required to form the first-conduction-type isolation region which passes through the third semiconductor region forming the structure for maintaining the reverse breakdown voltage. In this way, it is possible to reduce crystal defects due to thermal diffusion which is performed at a high temperature for a long time.

According to embodiments of the invention, since the rib portions are provided in the outer circumference of each of the chips in which a plurality of elements are arranged in the wafer, the first semiconductor region or the second electrode provided in the active region does not contact a support on which the wafer is placed, in the electric characteristic test which is performed for the wafer before the wafer is diced. Therefore, it is possible to prevent the first semiconductor region or the second electrode from being damaged. In this way, it is possible to prevent the deterioration of the breakdown voltage or leakage current characteristics of the element.

According to the semiconductor devices and the semiconductor device manufacturing methods of embodiments of the invention, it is possible to improve mechanical strength. In addition, according to the semiconductor devices and the semiconductor device manufacturing methods of embodiments of the invention, it is possible to reduce conduction loss and switching loss. Furthermore, according to the semiconductor devices and the semiconductor device manufacturing methods of embodiments of the invention, it is possible to improve yield.

Additional aspects and/or advantages will be set forth in part in the description which follows and, in part, will be apparent from the description, or may be learned by practice of the invention.

### BRIEF DESCRIPTION OF THE DRAWINGS

These and/or other aspects and advantages will become apparent and more readily appreciated from the following description of the embodiments, taken in conjunction with the accompanying drawings of which:

FIG. 1 is a cross-sectional view illustrating the structure of a semiconductor device according to a first embodiment.

FIG. 2 is a cross-sectional view illustrating the semiconductor device according to the first embodiment which is being manufactured.

FIG. 3 is a cross-sectional view illustrating the semiconductor device according to the first embodiment which is being manufactured.

FIG. 4 is a cross-sectional view illustrating the semiconductor device according to the first embodiment which is being manufactured.

FIG. 5 is a cross-sectional view illustrating the semiconductor device according to the first embodiment which is being manufactured.

FIG. 6 is a cross-sectional view illustrating the semiconductor device according to the first embodiment which is being manufactured.

FIG. 7 is a cross-sectional view illustrating the semiconductor device according to the first embodiment which is being manufactured.

FIG. 8 is a cross-sectional view illustrating the semiconductor device according to the first embodiment which is being manufactured.

FIG. 9 is a cross-sectional view illustrating the semiconductor device according to the first embodiment which is being manufactured.

FIG. 10 is a cross-sectional view illustrating the semiconductor device according to the first embodiment which is being manufactured.

FIG. 11 is a cross-sectional view illustrating the semiconductor device according to the first embodiment which is being manufactured.

FIG. 12 is a cross-sectional view illustrating the semiconductor device according to the first embodiment which is being manufactured.

FIG. 13 is a cross-sectional view illustrating the semiconductor device according to the first embodiment which is being manufactured.

FIG. 14 is a cross-sectional view illustrating the semiconductor device according to the first embodiment which is being manufactured.

FIG. 15 is a cross-sectional view illustrating the semiconductor device according to the first embodiment which is being manufactured.

FIG. 16 is a cross-sectional view illustrating the semiconductor device according to the first embodiment which is being manufactured.

FIG. 17 is a cross-sectional view illustrating the semiconductor device according to the first embodiment which is being manufactured.

FIG. 18 is a characteristic diagram illustrating the impurity concentration distribution of the semiconductor device according to the first embodiment.

FIG. 19 is a characteristic diagram illustrating the breakdown voltage characteristics of the semiconductor device according to the first embodiment.

FIG. 20 is a circuit diagram illustrating a simulation circuit for turning off the semiconductor device according to the first embodiment.

FIG. 21 is a characteristic diagram illustrating the relation between the surge voltage and gate resistance of the semiconductor device according to the first embodiment.

FIG. 22 is a characteristic diagram illustrating the relation between the surge voltage and gate resistance of the semiconductor device according to the first embodiment.

FIG. 23 is a cross-sectional view illustrating the structure of a semiconductor device according to a third embodiment.

FIG. 24 is a cross-sectional view illustrating the semiconductor device according to the third embodiment which is being manufactured.

FIG. 25 is a cross-sectional view illustrating the semiconductor device according to the third embodiment which is being manufactured.

FIG. 26 is a cross-sectional view illustrating the semiconductor device according to the third embodiment which is being manufactured.

FIG. 27 is a cross-sectional view illustrating the semiconductor device according to the third embodiment which is being manufactured.

FIG. 28 is a cross-sectional view illustrating the semiconductor device according to the third embodiment which is being manufactured.

FIG. 29 is a cross-sectional view illustrating the semiconductor device according to the third embodiment which is being manufactured.

FIG. 30 is a cross-sectional view illustrating the semiconductor device according to the third embodiment which is being manufactured.

FIG. 31 is a cross-sectional view illustrating the semiconductor device according to the third embodiment which is being manufactured.

FIG. 32 is a characteristic diagram illustrating the breakdown voltage characteristics of the semiconductor device according to the third embodiment.

FIG. 33 is a characteristic diagram illustrating the breakdown voltage characteristics of the semiconductor device according to the third embodiment.

FIG. 34 is a cross-sectional view illustrating the structure of an IGBT according to the related art.

FIG. 35 is a cross-sectional view illustrating the structure of an RB-IGBT according to the related art.

FIG. 36 is a cross-sectional view illustrating the cross-sectional structure of the semiconductor device according to the related art which is being manufactured.

FIG. 37 is a cross-sectional view illustrating the cross-sectional structure of the semiconductor device according to the related art which is being manufactured.

FIG. 38 is a cross-sectional view illustrating the cross-sectional structure of the semiconductor device according to the related art which is being manufactured.

### DESCRIPTION OF EMBODIMENTS

Reference will now be made in detail to the embodiments, examples of which are illustrated in the accompanying drawings, wherein like reference numerals refer to the like elements throughout. The embodiments are described below to explain the present invention by referring to the figures.

Hereinafter, semiconductor devices and methods of manufacturing the semiconductor device according to exemplary embodiments of the invention will be described in detail with reference to the accompanying drawings. In the specification and the accompanying drawings, in the layers or regions having “n” or “p” appended thereto, an electron or a hole is a major carrier. In addition, symbols “+” and “−” added to n or p mean that impurity concentration is higher and lower than that of the layer or the region without the symbols. In the description of the following embodiments and the accompanying drawings, the same components are denoted by the same reference numerals and the description thereof will not be repeated.

### First Embodiment

FIG. 1 is a cross-sectional view illustrating the structure of a semiconductor device according to a first embodiment. The semiconductor device according to the first embodiment is a field stop insulated gate bipolar transistor (FS-IGBT) with a planar structure. As illustrated in FIG. 1, the semiconductor device according to the first embodiment includes a termination structure 26 that reduces the electric field of one main surface (hereinafter, referred to as a first main surface) of an n⁻ drift region (third semiconductor region) 2, which is an n-type (second conduction type) semiconductor substrate, and maintains a breakdown voltage and an active region 27 in which a current flows when the semiconductor device is turned on.

The termination structure 26 is provided in the outer circumference of a chip in which the FS-IGBT is provided, which is the outside of the active region 27. In addition, the termination structure 26 comes into contact with the active region 27 and surrounds the active region 27. The active region 27 is provided in the inner circumference of the chip with a thickness t21 less than the thickness t22 of the outer circumference of the chip in which the termination structure 26 is provided. The termination structure 26 may be provided so as to extend from a portion of the outer circumference of the chip which is thicker than the inner circumference of the chip to a thin portion of the inner circumference of the chip, or it may be provided only in the portion of the outer circumference of the chip which is thicker than the inner circumference of the chip.

The portion of the outer circumference of the chip which is thicker than the inner circumference of the chip is provided so as to extend from the termination structure 26 to a dicing line in the outer circumference of the chip. The width of the portion of the outer circumference of the chip, which is thicker than the inner circumference of the chip, in a direction perpendicular to a direction (hereinafter, referred to as a first depth direction) from one main surface (first main surface) to the other main surface (hereinafter, referred to as a second main surface) of the n⁻ drift region 2 which includes the width (about 100 μm) of a dicing line is, for example, 300 μm in the entire chip. It is preferable that the thickness of the outer circumference of the chip be greater than, for example, 80 μm.

An n field stop region (second semiconductor region) 4 is provided on the second main surface of the n⁻ drift region 2 so as to extend from the active region 27 to the termination structure 26. The resistivity of the n⁻ drift region 2 is higher than that of the n field stop region 4. In the active region 27, the depth of the n field stop region 4 from the first main surface of the n⁻ drift region 2 in the first depth direction is less than that of the n field stop region 4 from the first main surface of the n⁻ drift region 2 in the first depth direction in the termination structure 26. In the active region 27, the depth of the n field stop region 4 in the first depth direction is equal to or greater than, for example, 1.5 μm.

In the active region 27, the thickness t11 of the n field stop region 4 is less than the thickness t12 of the n field stop region 4 in the termination structure 26. Specifically, the position of the interface between the n⁻ drift region 2 and the n field stop region 4 from the first main surface of the n⁻ drift region 2 in the first depth direction is the same from the active region 27 to the termination structure 26. In the termination structure 26, the position of a surface of the n field stop region 4 which is opposite to the n⁻ drift region 2 from the first main surface of the n⁻ drift region 2 in the first depth direction is deeper than that in the active region 27.

In the active region 27, a p collector region (first semiconductor region) 11 is provided on the front surface of the n field stop region 4 opposite to the n⁻ drift region 2. A collector electrode (second electrode) 12 comes into contact with a surface of the p collector region 11 opposite to the n field stop region 4. The p collector region 11 and the collector electrode 12 are provided so as to extend from the active region 27 to the termination structure 26. In the termination structure 26, a silicon oxide film (insulating region) 3 is provided between the n field stop region 4 and the p collector region 11.

The silicon oxide film 3 comes into contact with the n field stop region 4. The first position L1 of the silicon oxide film 3 from the first main surface of the n⁻ drift region 2 in the first depth direction is substantially the same as the second position L2 of the collector electrode 12 from the first main surface of the n⁻ drift region 2 in the first depth direction in the active region 27. In addition, a p-type region 1 which is a p-type (first conduction type) semiconductor substrate and has one main surface (hereinafter, referred to as a first main surface) coming into contact with the silicon oxide film 3 and the other main surface (hereinafter, referred to as a second main surface) coming into contact with the p collector region 11 is provided between the silicon oxide film 3 and the p collector region 11. Since the p-type region 1 is provided in the termination structure 26, the outer circumference of the chip is thicker than the inner circumference of the chip, as described above.

In the active region 27, a surface element structure of an FS-IGBT including, for example, a p base region (fourth semiconductor region) 5, an n⁺ emitter region (fifth semiconductor region) 6, a p⁺ base contact region 10, an n hole barrier region (sixth semiconductor region) 13, a gate insulating film 7, a gate electrode 8, and an emitter electrode (first electrode) 9 is formed on the first main surface of the n⁻ drift region 2. The surface element structure, the n⁻ drift region 2, the n field stop region 4, the p collector region 11, and the collector electrode 12 form a unit cell of the active region 27.

Specifically, the p base region 5 and the n hole barrier region 13 are selectively provided in a front surface layer of the first main surface of the n⁻ drift region 2. The n hole barrier region 13 comes into contact with the p base region 5 and covers the surface of the p base region 5 close to the n field stop region 4. The n⁺ emitter region 6 and the p⁺ base contact region 10 are selectively provided in a front surface layer of the p base region 5 opposite to (hereinafter, referred to as “close to the first main surface”) the n field stop region 4. The resistivity of the n⁺ emitter region 6 is less than that of the n⁻ drift region 2. The p⁺ base contact region 10 comes into contact with the n⁺ emitter region 6 and covers a surface of the n⁺ emitter region 6 close to the n field stop region 4. The resistivity of the p⁺ base contact region 10 is less than that of the p base region 5.

The gate electrode 8 is provided on the front surface (the surface of the n⁻ drift region 2 opposite to the n field stop region 4) of the p base region 5 interposed between the n⁻ drift region 2 and the n⁺ emitter region 6, with the gate insulating film 7 interposed therebetween. Specifically, the gate insulating film 7 is formed on the surfaces of the n⁻ drift region 2, the n hole barrier region 13, the p base region 5, and the n⁺ emitter region 6, and the gate electrode 8 is provided on the gate insulating film 7. The emitter electrode 9 comes into contact with the p base region 5 and the n⁺ emitter region 6 on the first main surface side of the n⁻ drift region 2 and electrically disconnects the p base region 5 and the n⁺ emitter region 6. The emitter electrode 9 is insulated from the gate electrode 8 by an interlayer insulating film 16.

In the termination structure 26, a structure for maintaining the breakdown voltage of the FS-IGBT is provided in the first main surface of the n⁻ drift region 2. Specifically, a plurality of floating p regions (field limiting rings and seventh semiconductor regions) 14 are selectively provided in the front surface layer of the first main surface of the n⁻ drift region 2. In addition, a plurality of field plate regions 17 are provided on the first main surface of the n⁻ drift region 2. Each field plate region 17 is electrically connected to a p⁺-type region which has a resistivity less than that of the field limiting ring 14 and is provided in a front surface layer of the first main surface side of the field limiting ring 14. The field plate region 17 is made of polysilicon.

An n⁺ region (eighth semiconductor region) 15 is provided in the front surface layer of the first main surface of the n⁻ drift region 2 so as to be separated from the field plate region 17. The n⁺ region 15 is provided closer to the outer circumference of the chip than the field plate region 17. The resistivity of the n⁺ region 15 is less than that of the n⁻ drift region 2. A field plate 18 comes into contact with the n⁺ region 15. Each field plate region 17 is insulated from the field plate 18 by an interlayer insulating film. As such, the field limiting rings 14, the n⁺ region 15, the field plate regions 17, and the field plate 18 form the termination structure 26 of the FS-IGBT.

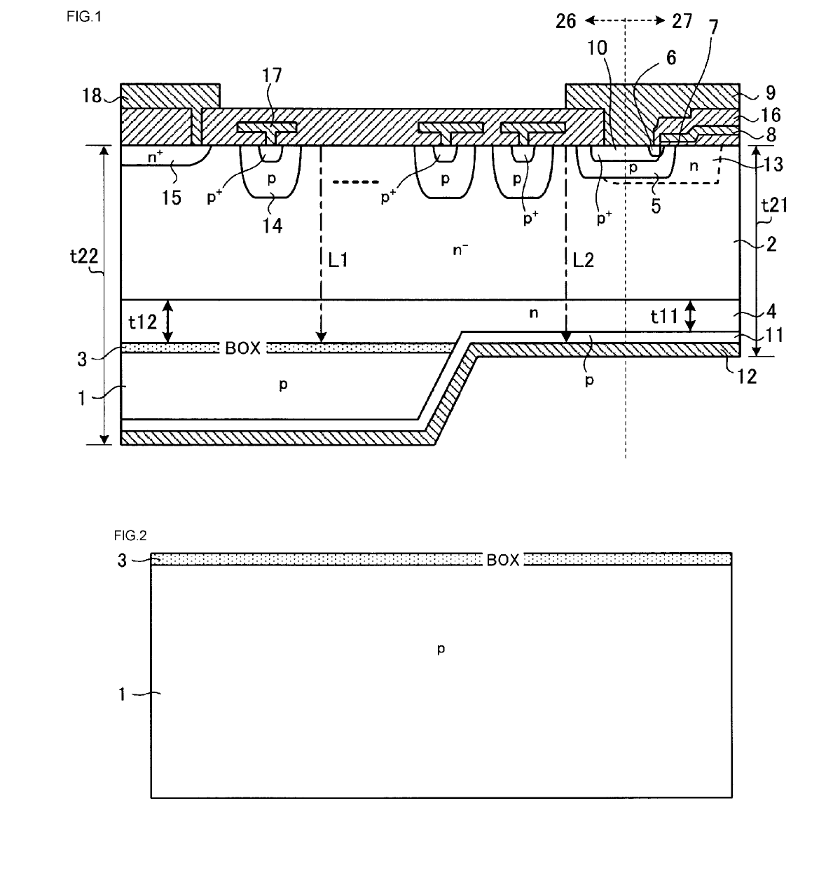

Next, a method of manufacturing the FS-IGBT illustrated in FIG. 1 will be described. FIGS. 2 to 17 are cross-sectional views illustrating the semiconductor device according to the first embodiment which is being manufactured. First, as illustrated in FIG. 2, a p-type semiconductor wafer (hereinafter, referred to as a CZ wafer; a first wafer) manufactured by, for example, a Czochralski (CZ) method is prepared. The p-type CZ wafer (hereinafter, referred to as a p-type CZ wafer 1) is a p-type semiconductor substrate which is the p-type region 1. Then, the silicon oxide film 3 is formed on the first main surface of the p-type CZ wafer 1 by a thermal oxidation method or a deposition method. The thickness of the silicon oxide film 3 may be in the range of, for example, 100 nm to 300 nm.

Then, as illustrated in FIG. 3, an n-type FZ wafer (second wafer) manufactured by, for example, an FZ method is prepared separately from the p-type CZ wafer 1. The n-type FZ wafer (hereinafter, referred to as an n-type FZ wafer 2) is an n-type semiconductor substrate forming the n⁻ drift region 2. The resistivity of the n-type FZ wafer 2 may be in the range of 13 Ω·cm to 20 Ω·cm. Then, a screen oxide film 31 is formed on the second main surface of the n-type FZ wafer 2. The thickness of the screen oxide film 31 may be, for example, about 30 nm.

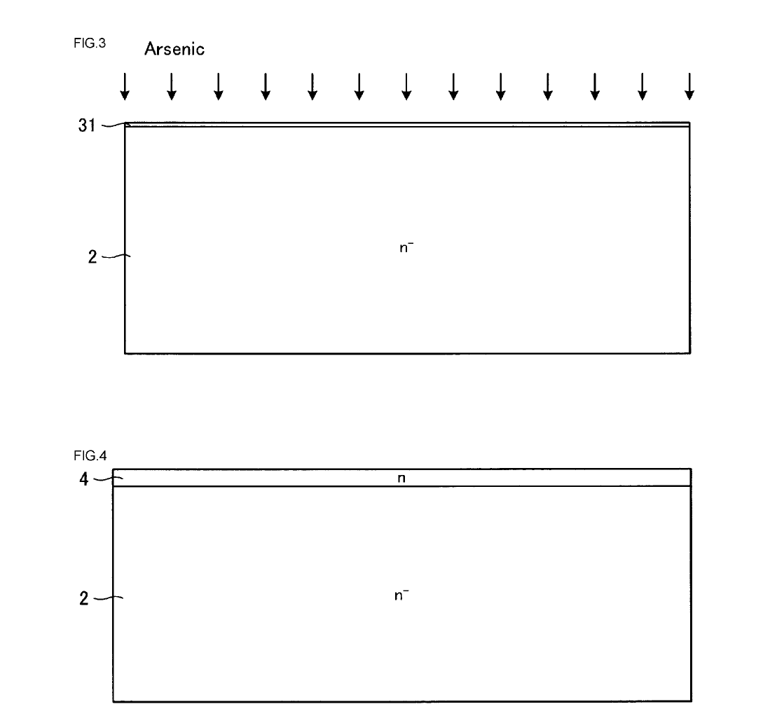

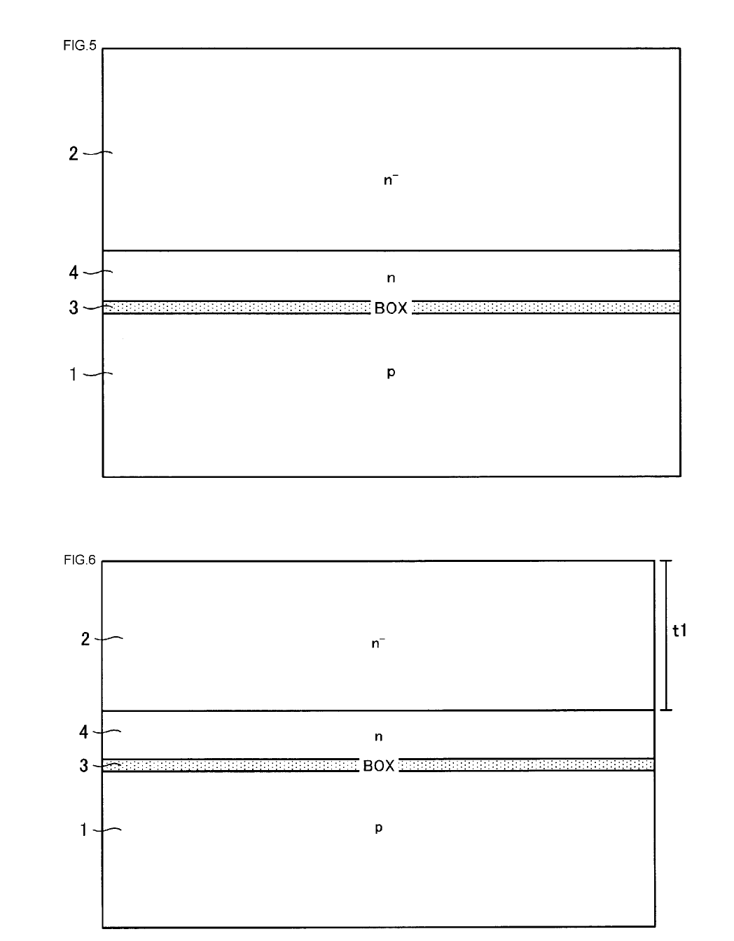

Then, n-type impurity ions, such as arsenic (As) ions or antimony (Sb) ions, are implanted into the second main surface of the n-type FZ wafer 2 through the screen oxide film 31. Then, as illustrated in FIG. 4, a thermal annealing process is performed to form the n field stop region (second conduction type semiconductor region) 4 in the second main surface of the n-type FZ wafer 2. The ion implantation conditions for forming the n field stop region 4 may be, for example, a dose of 1×10¹² cm⁻² to 3×10¹² cm⁻² and an acceleration energy of 100 KeV.

For example, the thermal annealing process for forming the n field stop region 4 may be performed at a temperature of 900° C. for 30 minutes in a nitrogen (N) atmosphere. The thermal annealing process for forming the n field stop region 4 makes it possible to prevent the surface morphology of the n-type FZ wafer 2 from deteriorating. Then, the screen oxide film 31 on the second main surface of the n-type FZ wafer 2 is removed.

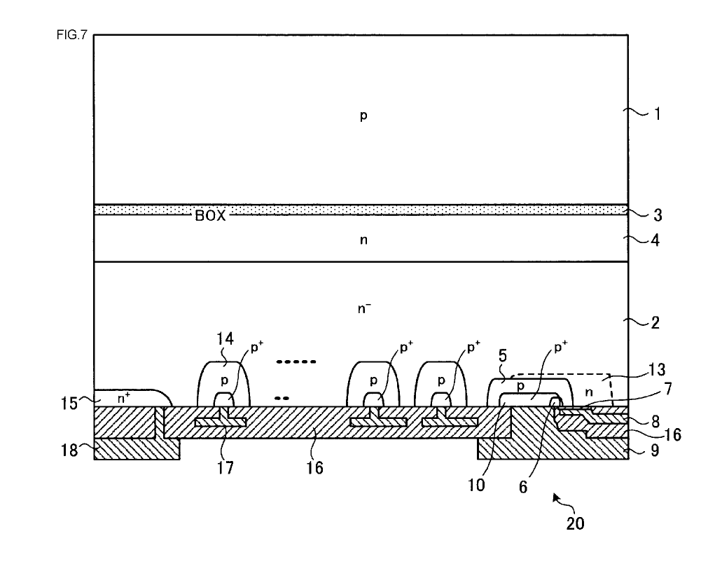

Then, as illustrated in FIG. 5, the first main surface of the p-type CZ wafer 1 on which the silicon oxide film 3 is formed is bonded to the second main surface of the n-type FZ wafer 2 in which the n field stop region 4 is formed. In this case, the first main surface of the p-type CZ wafer 1 and the second main surface of the n-type FZ wafer 2 are bonded to each other with weak force, with a native oxide film which is formed on the n field stop region 4 of the n-type FZ wafer 2 interposed therebetween. Then, the thermal annealing process is performed for an SOI (Silicon on Insulator) wafer obtained by bonding the n-type FZ wafer 2 and the p-type CZ wafer 1. In this way, the bonding between the n-type FZ wafer 2 and the p-type CZ wafer 1 is strengthened.

The n field stop region 4 is thermally diffused by the thermal annealing process for bonding the p-type CZ wafer 1 and the n-type FZ wafer 2. In this way, the diffusion depth of the n field stop region 4 is more than that before the thermal annealing process for bonding the p-type CZ wafer 1 and the n-type FZ wafer 2 is performed. For example, the thermal annealing process for bonding the p-type CZ wafer 1 and the n-type FZ wafer 2 may be performed at a temperature of 1000° C. to 1200° C. for two hours in a nitrogen atmosphere or an argon (Ar) atmosphere.

Then, as illustrated in FIG. 6, the SOI wafer obtained by bonding the p-type CZ wafer 1 and the n-type FZ wafer 2 is polished from the main surface (hereinafter, simply referred to as the first main surface of the n-type FZ wafer 2) on the side of the n-type FZ wafer 2 until the n-type FZ wafer 2 has a predetermined thickness t1. For example, when an FS-IGBT with a breakdown voltage class of 400 V is manufactured, the thickness t1 of the n-type FZ wafer 2 is reduced to 40 μm. In this way, the SOI wafer in which the p-type CZ wafer 1, the silicon oxide film 3, and the n-type FZ wafer 2 are laminated is completed.

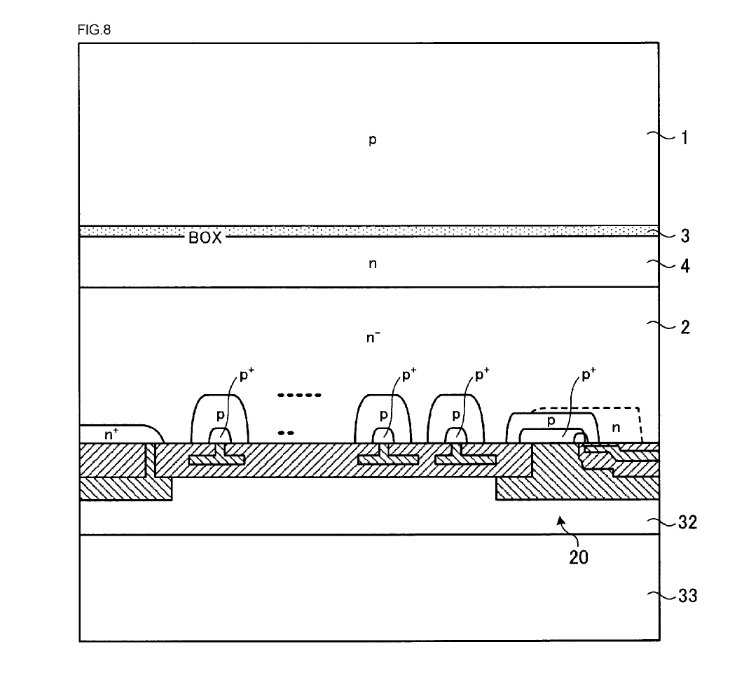

Then, as illustrated in FIG. 7, in the active region, a surface element structure 20 of the FS-IGBT including, for example, the p base region 5, the n⁺ emitter region 6, the p⁺ base contact region 10, the n hole barrier region 13, the gate insulating film 7, the gate electrode 8, and the emitter electrode 9 is formed on the first main surface of the n-type FZ wafer 2 by a general method. In the termination structure, a structure which includes, for example, the field limiting rings 14, the n⁺ region 15, the field plate regions 17, and the field plate 18 and maintains the breakdown voltage of the FS-IGBT is formed on the first main surface of the n-type FZ wafer 2 by a general method.

The n field stop region 4 formed at the interface between the n-type FZ wafer 2 and the p-type CZ wafer 1 is thermally diffused by the heat treatment which is performed to form the surface element structure 20 of the FS-IGBT and the structure for maintaining the breakdown voltage and the diffusion depth of the n field stop region 4 increases. Then, a passivation film (not illustrated), such as a polyimide film or a nitride film, is formed on the entire first main surface of the n-type FZ wafer 2 on which, for example, the surface element structure 20 is formed. Then, the passivation film is etched such that the electrode region of the surface element structure 20 is exposed and an electrode pad region is formed.

Then, as illustrated in FIG. 8, a protective resist 32 is applied onto the entire first main surface of the n-type FZ wafer 2 on which, for example, the surface element structure 20 is formed. Then, the protective resist 32 is modified and hardened and a back grind tape (BG tape) 33 is attached to the protective resist 32. At that time, as illustrated in FIG. 9, the n-type FZ wafer 2 of the SOI wafer is attached to the BG tape 33 through the protective resist 32, with the surface element structure 20 formed in each element forming region, which will be an individual chip when the wafer is cut into chips, in the first main surface of the n-type FZ wafer 2.

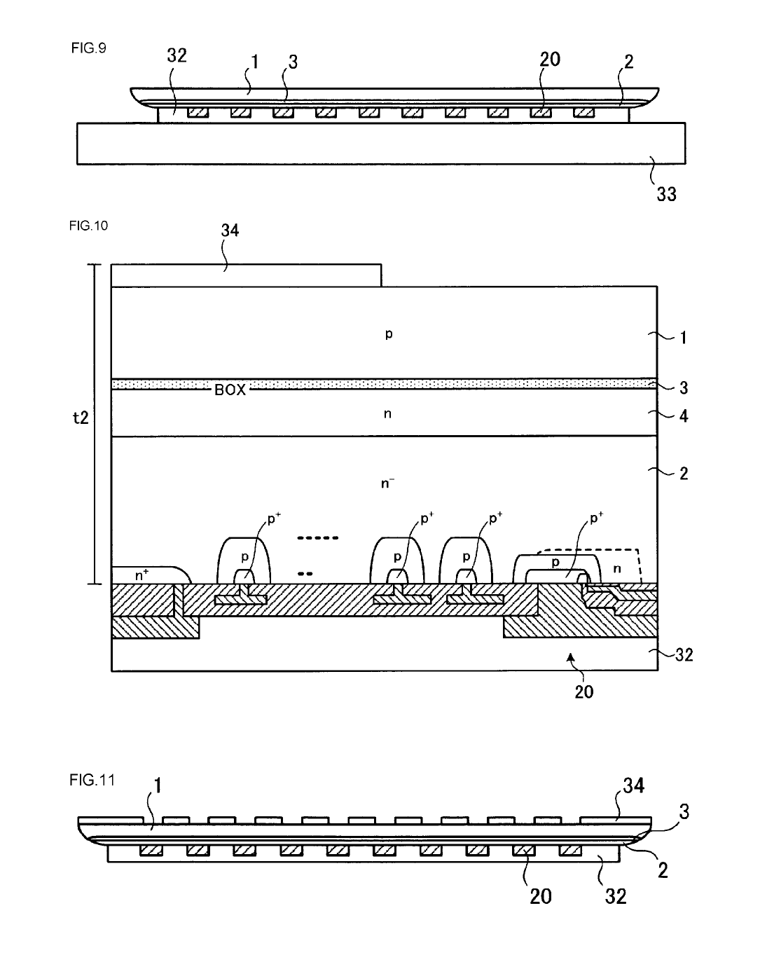

Then, as illustrated in FIG. 10, the main surface (hereinafter, simply referred to as the second main surface of the p-type CZ wafer 1) of the SOI wafer on the side of the p-type CZ wafer 1 is polished such that the thickness t2 of the SOI wafer is greater than 80 μm, for example, until the thickness t2 is 100 μm. Then, the BG tape 33 is removed from the first main surface of the n-type FZ wafer 2 and the SOI wafer is cleaned. Then, the first main surface of the p-type CZ wafer 1 is etched such that the thickness of the p-type CZ wafer 1 is, for example, about 5 μm to 20 μm.

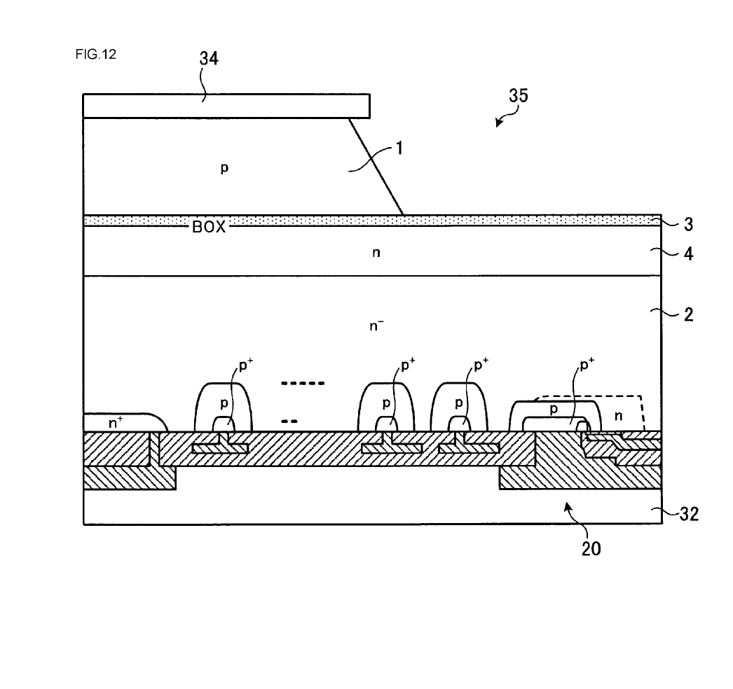

Then, a resist mask 34 having openings through which the active region of the p-type CZ wafer 1 is exposed is formed on the first main surface of the p-type CZ wafer 1. In this way, as illustrated in FIG. 11, portions of the second main surface of the p-type CZ wafer 1 which are opposite to the surface element structures 20 formed on the first main surface of the n-type FZ wafer 2 are exposed through the openings of the resist mask 34. Then, as illustrated in FIG. 12, anisotropic wet etching is performed using the resist mask 34 as a mask to form grooves 35 which extend from the second main surface of the p-type CZ wafer 1 to the silicon oxide film 3. That is, the silicon oxide film 3 functions as an etching stopper.

A plurality of grooves 35 having a trapezoidal shape in which the second main surface is longer than the first main surface in a cross-sectional view are formed in the p-type CZ wafer 1 by anisotropic etching for forming the grooves 35. The grooves 35 formed in the p-type CZ wafer 1 cause the thickness of the chip in the active region to be less than that of the chip in the termination structure after the FS-IGBT is completed. A solution used in etching for forming the grooves 35 may include, for example, a tetramethylammonium hydroxide (TMAH) solution as a main component. Then, the resist mask 34 used to form the grooves 35 is removed.

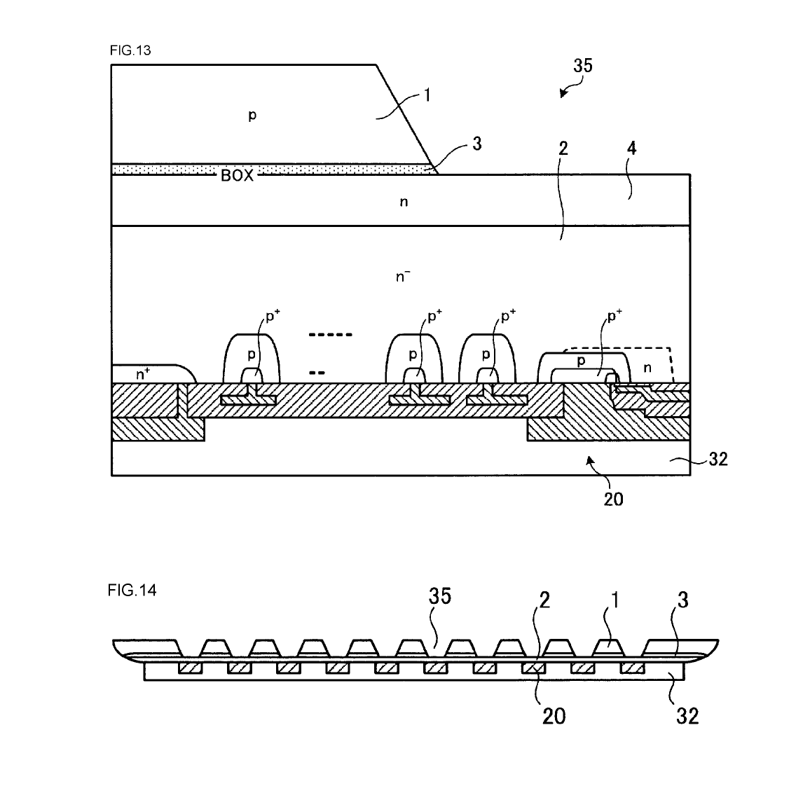

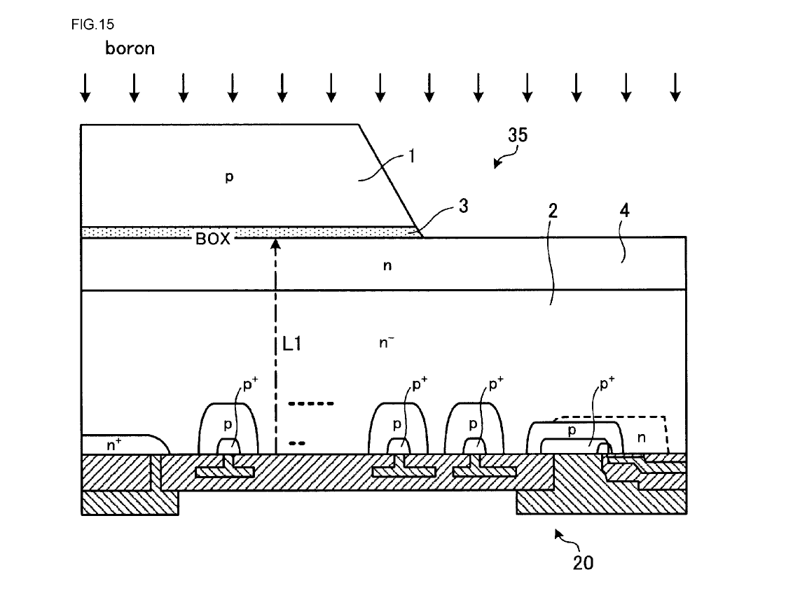

Then, as illustrated in FIG. 13, wet etching is performed to remove the silicon oxide film 3 which is exposed from the bottoms of the grooves 35. At that time, as illustrated in FIG. 14, portions of the second main surface of the n-type FZ wafer 2 which are opposite to the surface element structures 20 formed on the first main surface of the n-type FZ wafer 2 are exposed from the bottom of each groove 35. In addition, as illustrated in FIG. 15, the silicon oxide film 3 exposed from the bottoms of the grooves 35 is removed and the silicon oxide film 3 is arranged at the first position L1 from the first main surface of the n⁻ drift region 2 in the first depth direction in the active region 27. Then, the protective resist 32 covering the first main surface of the n-type FZ wafer 2 is removed and the SOI wafer is cleaned.

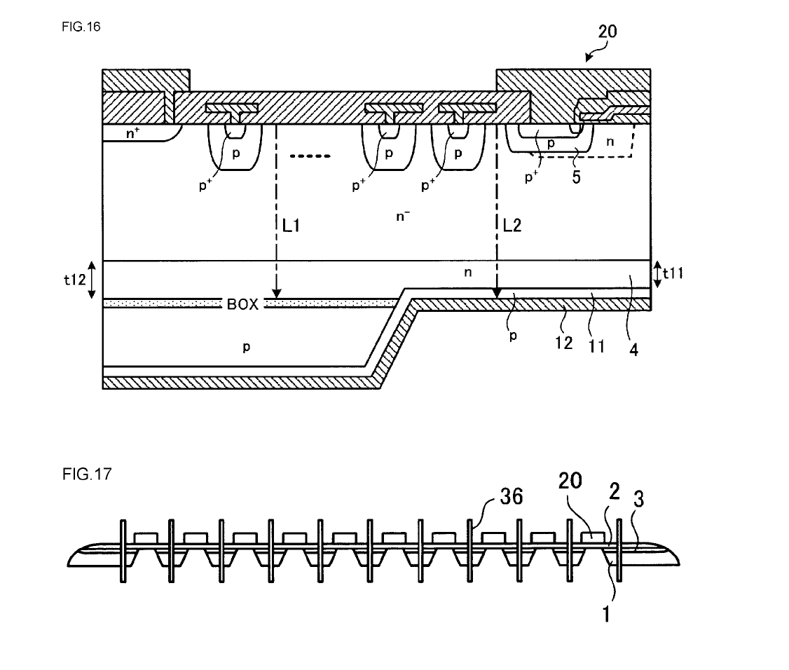

Then, boron (B) ions are implanted into the entire surface of the SOI wafer on the side of the p-type CZ wafer 1, that is, the second main surface of the p-type CZ wafer 1, the surface of the p-type CZ wafer 1 exposed from the side walls of the grooves 35, and the second main surface of the n-type FZ wafer 2 exposed from the bottoms of the grooves 35. Then, a laser annealing process is performed for the entire surface of the SOI wafer on the side of the p-type CZ wafer 1 to activate the boron implanted into the entire surface of the SOI wafer on the side of the p-type CZ wafer 1. In this way, as illustrated in FIG. 16, the p collector region 11 is formed in the entire surface of the SOI wafer on the side of the p-type CZ wafer 1.

Since the p collector region 11 is formed in the second main surface of the n-type FZ wafer 2 exposed from the bottoms of the grooves 35, the thickness t11 of the n field stop region 4 in the active region 27 is less than the thickness t12 of the n field stop region 4 in the termination structure 26. The ion implantation conditions for forming the p collector region 11 may be, for example, a dose of 5×10¹² cm⁻² to 1.5×10¹³ cm⁻² and an acceleration energy of 30 KeV to 60 KeV. For example, the laser annealing process for forming the p collector region 11 may be performed at an energy density of 1.0 J/cm² to 2.0 J/cm² by a YAG laser with a wavelength of 532 nm.

Then, a metal electrode material forming the collector electrode 12 is deposited on the entire surface of the SOI wafer on the side of the p-type CZ wafer 1. In this way, the collector electrode 12 is arranged at the second position L2 from the first main surface of the n⁻ drift region 2 in the first depth direction in the active region 27. Then, the metal electrode material deposited on the entire surface of the SOI wafer on the side of the p-type CZ wafer 1 is thermally annealed to form the collector electrode 12 on the entire surface of the p collector region 11. The thermal annealing process for forming the collector electrode 12 may be performed, for example, at a temperature of 180° C. to 330° C. in an inert atmosphere. In this way, as illustrated in FIG. 17, a plurality of FS-IGBTs illustrated in FIG. 1 are formed in the SOI wafer. Then, the SOI wafer is diced into individual chips along dicing lines 36. In this way, the FS-IGBT illustrated in FIG. 1 is completed.

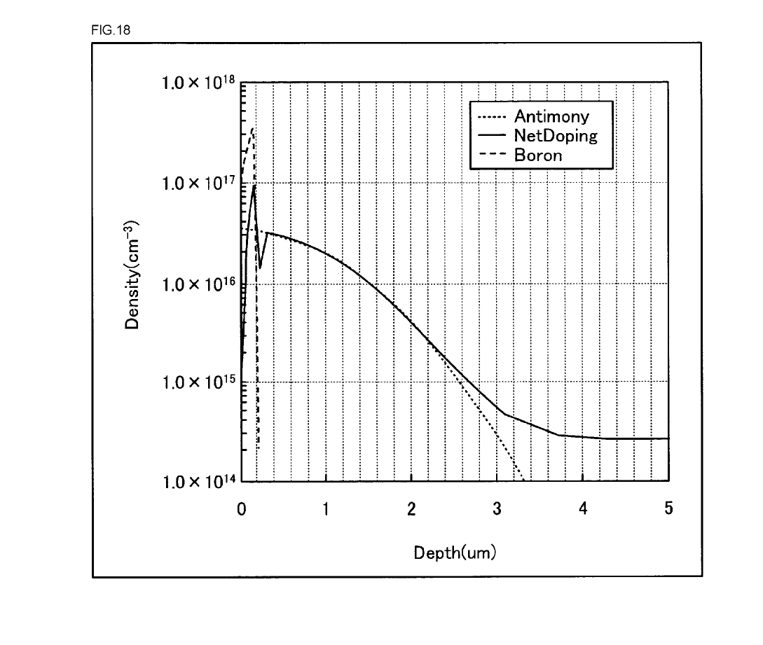

Next, the electric characteristics of the FS-IGBT illustrated in FIG. 1 will be described. First, the impurity concentration distribution of the p collector region 11 will be described. FIG. 18 is a characteristic diagram illustrating the impurity concentration distribution of the semiconductor device according to the first embodiment. FIG. 18 illustrates the impurity concentration distribution in the vicinity of the p collector region 11 when the n field stop region 4 and the p collector region 11 are formed under the following conditions. In ion implantation for forming the n field stop region 4, a dopant was antimony (Sb) and the dose thereof was 3×10¹² cm⁻². In ion implantation for forming the p collector region 11, a dopant was boron, the dose thereof was 1×10¹³ cm⁻², and acceleration energy was 45 KeV.

The laser annealing process for forming the p collector region 11 was performed at an energy density of 1.4 J/cm². Then, impurity concentration in the vicinity of the p collector region 11 was measured. In FIG. 18, the depth of the interface between the collector electrode 12 and the p collector region 11 is 0 (horizontal axis). The antimony concentration distribution illustrated in FIG. 18 is the simulation result. The boron concentration distribution illustrated in FIG. 18 is the measurement result obtained by a spreading sheet resistance method. The distribution of net doping concentration is net doping concentration when the resistivity of the n⁻ drift region 2 is 17 Ω·cm. The result illustrated in FIG. 18 proved that the depth of the n field stop region 4 made of antimony was about 3.8 μm and the activation rate thereof was approximately 100%.

Tokura, Norihito et al., “Milestones Achieved in IGBT Development over the Last 25 Years (1984 to 2009) (FIG. 8),” IEEE J Transaction on Al, Volume 131, Issue 1, 2011, pp. 1 to 8 discloses a structure in which, even when the acceleration energy of ion implantation is 620 KeV, the range of an n field stop region according to the related art formed by implanting phosphorous (P) ions into a thin wafer is about 0.8 μm. In addition, even when the heating temperature of the thermal annealing process for a collector electrode which is formed on the surface of the n field stop region with a p collector region interposed therebetween is 450° C. which is the allowable limit temperature of the collector electrode, the activation rate of the n field stop region is no more than about 20%.

In addition, Thomas Gutt et al., “Deep melt activation using laser thermal annealing for IGBT thin wafer technology (FIG. 5),” Proceedings of The 22nd International Symposium on Power Semiconductor Devices & IC's, 2011, pp. 29 to 32 disclose a structure in which, even when the wavelength λ of the laser is 306 nm and energy density is 3.7 J/cm², the depth of fusion of silicon is equal to or less than 250 nm. The activation rate of phosphorus is rapidly reduced in a portion which is deeper than the depth of fusion. Therefore, a method of manufacturing the semiconductor device according to the first embodiment can form the n field stop region with a large diffusion depth, as compared to the related art in which the n field stop region is formed after the surface element structure is formed.

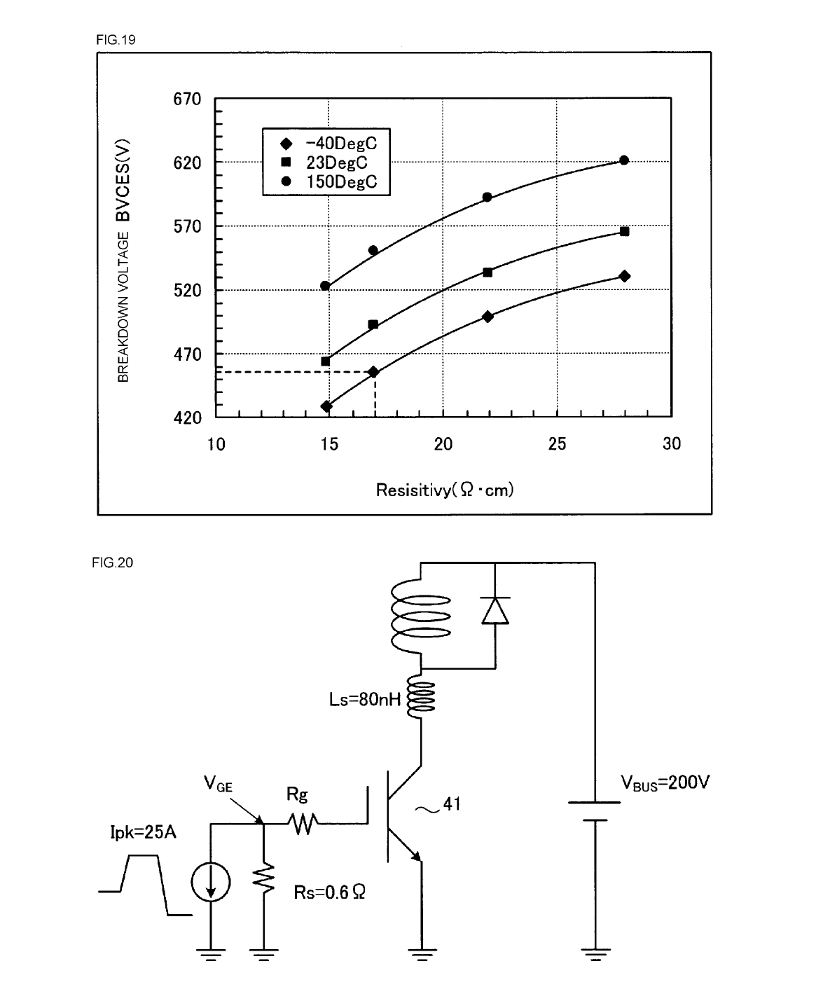

Next, the breakdown voltage of the FS-IGBT and the resistivity of the n⁻ drift region 2 according to the first embodiment will be described. FIG. 19 is a characteristic diagram illustrating the breakdown voltage characteristics of the semiconductor device according to the first embodiment. FIG. 19 illustrates an element breakdown voltage and the resistivity of the n⁻ drift region 2 when the half pitch (the distance from the interface between the active region 27 and the termination structure 26 to the end of the active region 27 opposite to the interface) of the active region is 15 μm and the dose of ion implantation for forming the n hole barrier region 13 is 2×10¹² cm⁻². It is assumed that a distance T_{SUB} from the silicon oxide film 3 to the front surface of the element (the first main surface of the n-type FZ wafer) is 37 μm. When the breakdown voltage was guaranteed up to the lower limit, −40° C., of the temperature range, the range of a variation in the distance T_{SUB} from the silicon oxide film 3 to the front surface of the element was from −3 μm to +3 μm, and the range of a variation in the resistivity of the n⁻ drift region 2 was from −8% to +8%, it was confirmed that the average thickness of the n⁻ drift region 2 was 40 μm and the average resistivity ρ of the n⁻ drift region 2 was 17 Ω·cm⁻².

As the thickness of the n-type FZ wafer, which will be the n⁻ drift region 2, is reduced, the amount of charge stored in the n⁻ drift region 2 in a conductive state is reduced. Therefore, a current variation di/dt when the element is turned off increases and an avalanche voltage between the collector and the emitter is increased by the parasitic inductance of the circuit. Therefore, it is necessary to reduce the peak voltage of the element to be equal to or less than a breakdown voltage. Next, a surge voltage and gate resistance when the element is turned off will be described.

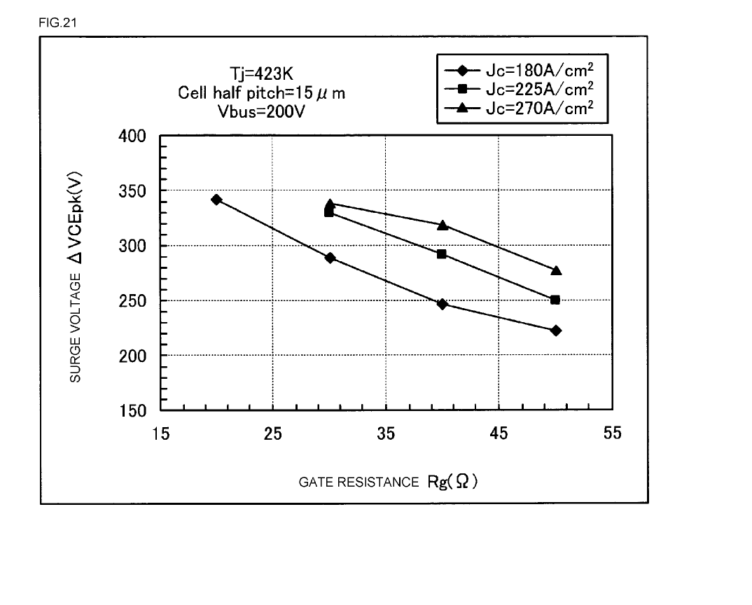

FIG. 20 is a circuit diagram illustrating a simulation circuit for turning off the semiconductor device according to the first embodiment. FIG. 21 is a characteristic diagram illustrating the relation between the surge voltage and the gate resistance of the semiconductor device according to the first embodiment. The surge voltage is the difference between the avalanche voltage and a bus voltage. As illustrated in FIG. 20, as the semiconductor device according to the first embodiment, an IGBT 41 is connected to the simulation circuit. Turn-off characteristics are measured under the following conditions: the bus voltage V_{BUS}=200 V; a peak current Ipk=25 A; parasitic inductance Ls=80 nH; a junction temperature Tj=150° C.; the distance T_{SUB} from the silicon oxide film 3 to the front surface of the element is 40 μm; and the resistivity p of the n⁻ drift region 2 is 17 Ω·cm.

As illustrated in FIG. 19, it is preferable that, in the IGBT with the planar structure illustrated in FIG. 1, the rated current density of the active region 27 be equal to or less than 270 A/cm² and the resistance Rg of the gate which is generally made of polysilicon be equal to or more greater than 40Ω, when the following are considered: the lower limit of the range of the resistivity of the n⁻ drift region 2; the lower limit of the range of the distance T_{SUB} from the silicon oxide film 3 to the front surface of the element; the breakdown voltage at a junction temperature Tj of 150° C. is about 520 V; and a dynamic breakdown voltage when a current equal to or greater than the rated current is turned off is lower than a static breakdown voltage. In addition, a reduction in the parasitic inductance of the circuit is more necessary compared to a case for a device with a higher breakdown voltage associate with a large substrate thickness.

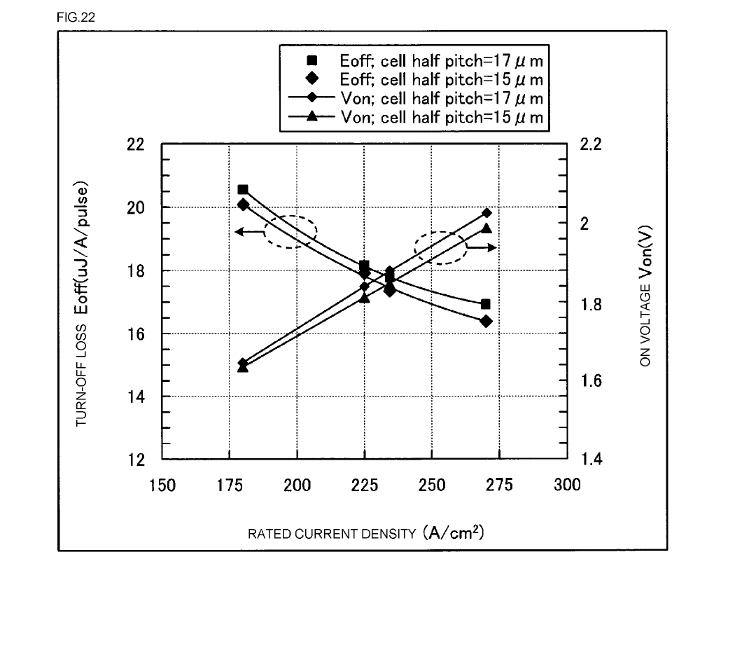

Next, the relation among rated current density, turn-off loss Eoff, and an on-voltage Von will be described. FIG. 22 is a characteristic diagram illustrating the relation between the surge voltage and the gate resistance of the semiconductor device according to the first embodiment. The turn-off characteristics are measured under the following conditions: the junction temperature Tj=150° C.; the distance T_{SUB} from the silicon oxide film 3 to the front surface of the element is 40 μm; the resistivity ρ of the n⁻ drift region 2 is 17 Ω·cm; and the rated current is 150 A. The result illustrated in FIG. 22 proved that, when the rated current density was in the range of 175 A/cm² to 275 A/cm², the turn-off loss Eoff was equal to or less than 22 μJ/A/Pulse and the on voltage Von was equal to or less than 2.1V.

As described above, according to the semiconductor device of the first embodiment, the thickness t22 of the chip in the termination structure 26 is more than the thickness t21 of the chip in the active region 27. Therefore, portions (hereinafter, referred to as rib portions) with a thickness larger than the thickness t21 of the chip in the active region 27 can be provided in the outer circumference of each of the chips in which a plurality of elements are arranged in the wafer so as to surround the active region 27. Specifically, for example, the rib portions are arranged in a lattice shape along the scrub lines of the wafer. The width of the rib portion from the outer circumference of the chip to the inner circumference of the chip is, for example, about 300 μm including the width of the termination structure and the scrub line in the entire chip. In addition, the thickness of the rib portion may be equal to or greater than, for example, 80 μm which is the limit value (limit thickness) of the thickness of the wafer when the wafer is thinned. Therefore, even when the thickness of the chip in the active region 27 is reduced to a design value required to obtain a desired breakdown voltage, the rib portions provided in the outer circumference of the chip can reduce the concentration of stress on the wafer. As a result, the wafer is less likely to be broken than the wafer according to the related art in which the rib portions are formed only in the outer circumference of the wafer. Therefore, it is possible to improve the mechanical strength of the wafer.

According to embodiments of the invention, since the thickness of the chip in the active region 27 can be reduced to a design value required to obtain a desired breakdown voltage, it is possible to improve the tradeoff relation between the conduction loss and switching loss of the element. Therefore, it is possible to reduce the conduction loss and switching loss.

According to embodiments of the invention, the n field stop region 4 is formed before, for example, the surface element structure 20 of the element is formed. Therefore, when the p-type CZ wafer 1 is bonded to the n-type FZ wafer 2 and when, for example, the surface element structure 20 of the element is formed, it is possible to thermally diffuse the n field stop region 4. Therefore, it is possible to increase the diffusion depth of the n field stop region 4, as compared to the related art in which, after the surface element structure 20 is formed in the wafer, the wafer is thinned and the n field stop region 4 is formed in the thin wafer. As a result, it is possible to reduce a leakage current which occurs due to the thin n field stop region 4 in the related art. It is possible to reduce conduction loss and switching loss.

According to embodiments of the invention, since the rib portions are provided in the outer circumference of each of the chips in which a plurality of elements are arranged in the wafer, the p collector region 11 or the collector electrode 12 provided in the active region 27 does not contact a support on which the wafer is placed, in the electric characteristic test which is performed for the wafer when the wafer is diced. Therefore, it is possible to prevent the p collector region 11 or the collector electrode 12 from being damaged. In this way, it is possible to prevent the deterioration of the breakdown voltage or leakage current characteristics of the element. As a result, it is possible to improve the yield of the element.

### Second Embodiment

A semiconductor device according to a second embodiment will be described. The semiconductor device according to the second embodiment differs from that according to the first embodiment in that an IGBT has a surface element structure which is a trench structure.

In the semiconductor device according to the second embodiment, a p base region is selectively provided in a surface layer of a first main surface of an n⁻ drift region 2 in an active region. A trench is provided so as to extend from the surface of the p base region close to the first main surface to an n⁻ drift region through the p base region. A gate insulating film is provided along the side wall and bottom of the trench. A gate electrode is buried in the gate insulating film. An n⁺ emitter region is selectively provided in the p base region. The n⁺ emitter region is provided so as to come into contact with the gate insulating film on the side wall of the trench.

The semiconductor device according to the second embodiment is similar to the semiconductor device according to the first embodiment except that the surface element structure is a gate structure. In a method of manufacturing the semiconductor device according to the second embodiment, the gate structure is formed by a general method when the surface element structure is formed in the semiconductor device according to the first embodiment. The method of manufacturing the semiconductor device according to the second embodiment is similar to the method of manufacturing the semiconductor device according to the first embodiment except for a process of forming the surface element structure which is the gate structure.

As described above, according to the semiconductor device of the second embodiment, it is possible to obtain the same effect as that obtained by the semiconductor device according to the first embodiment. Since the surface element structure is the gate structure, it is possible to reduce the turn-off loss Eoff and the on voltage Von.

### Third Embodiment

Next, a semiconductor device according to a third embodiment will be described. FIG. 23 is a cross-sectional view illustrating the structure of the semiconductor device according to the third embodiment. The semiconductor device according to the third embodiment differs from the semiconductor device according to the first embodiment in that it has a structure for maintaining a reverse breakdown voltage.

The semiconductor device according to the third embodiment is a reverse blocking IGBT (RB-IGBT). As illustrated in FIG. 23, in the semiconductor device according to the third embodiment, a p collector region 11 is provided in a second main surface of an n⁻ drift region 2 in an active region 27. An n field stop region 4 is provided between the n⁻ drift region 2 and the p collector region 11.

In a termination structure 26, a first p⁺ diffusion separation layer (ninth semiconductor region) 24A is provided in a surface layer of the second main surface of the n⁻ drift region 2 so as to be deeper than the p collector region 11 and to overlap a silicon oxide film 3 in a direction (hereinafter, referred to as a second depth direction) from the p collector region 11 to the n⁻ drift region 2. The first p⁺ diffusion separation layer 24A comes into contact with the entire surface of the silicon oxide film 3 close to the n⁻ drift region 2.

In the termination structure 26, a second p⁺ diffusion separation layer (tenth semiconductor region) 24B is provided in a surface layer of the first main surface of the n⁻ drift region 2 so as to be separated from the field plate region 17 and to come into contact with the first p⁺ diffusion separation layer 24A. The second p⁺ diffusion separation layer 24B is provided closer to the outer circumference of the chip than the field plate region 17. A field plate 18 comes into contact with the second p⁺ diffusion separation layer 24B. The first p⁺ diffusion separation layer 24A and the second p⁺ diffusion separation layer 24B make it possible to obtain a reverse breakdown voltage. The semiconductor device according to the third embodiment is similar to the semiconductor device according to the first embodiment except for the first p⁺ diffusion separation layer 24A and the second p⁺ diffusion separation layer 24B.

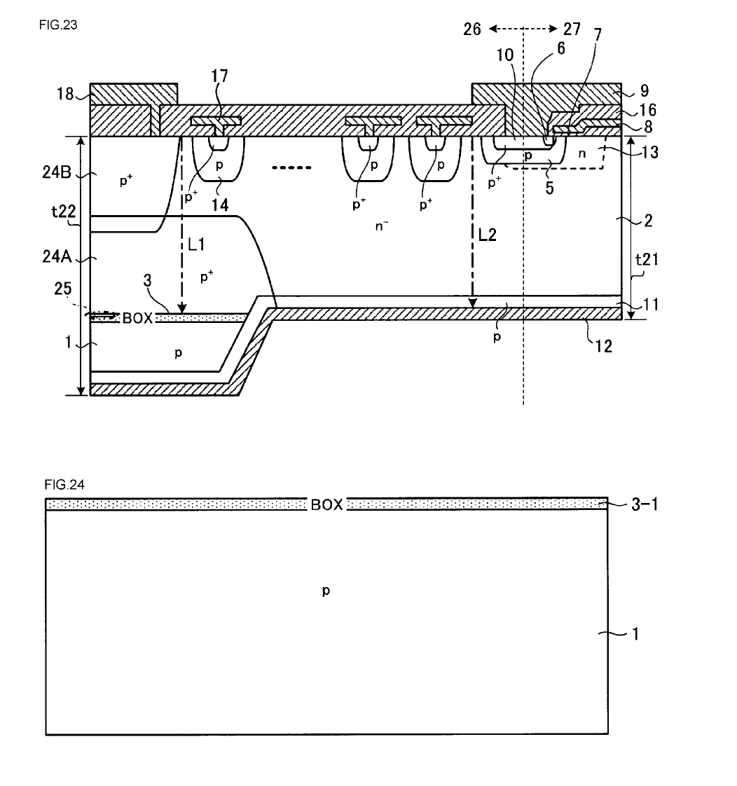

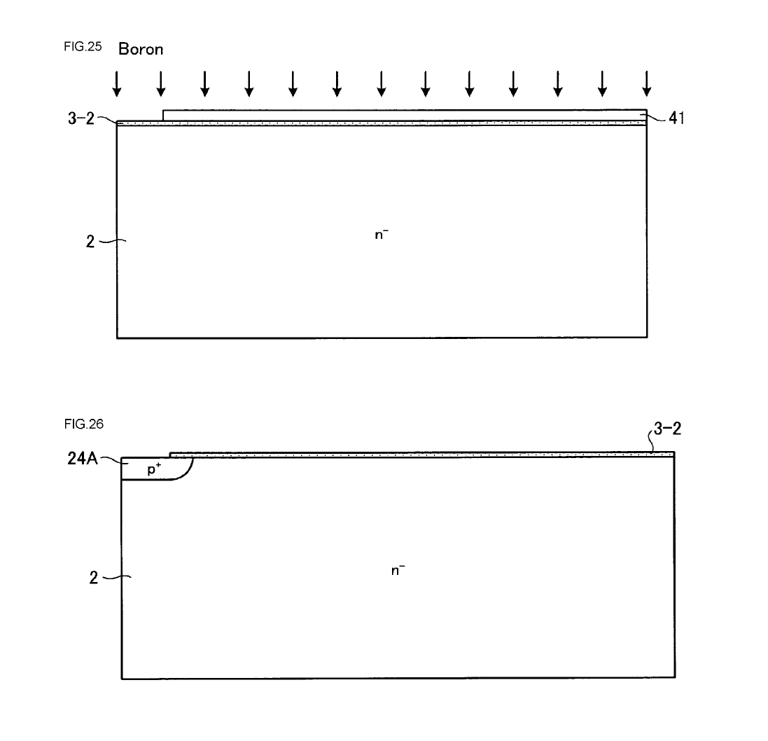

Next, a method of manufacturing the RB-IGBT illustrated in FIG. 23 will be described. FIGS. 24 to 31 are cross-sectional views illustrating the semiconductor device according to the third embodiment which is being manufactured. First, as illustrated in FIG. 24, similarly to the first embodiment, a silicon oxide film 3-1 is formed on the first main surface of, for example, a p-type CZ wafer (hereinafter, referred to as a p-type CZ wafer 1) which is a p-type region 1. The thickness of the silicon oxide film 3-1 may be in the range of, for example, 100 nm to 300 nm. Then, as illustrated in FIG. 25, similarly to the first embodiment, for example, an n-type FZ wafer (hereinafter, referred to as an n-type FZ wafer 2) is prepared separately from the p-type CZ wafer 1. Then, a screen oxide film 3-2 is formed on the second main surface of the n-type FZ wafer 2. The thickness of the screen oxide film 3-2 may be, for example, about 30 nm.

Then, a resist mask 41 having an opening for forming the first p⁺ diffusion separation layer (first-conduction-type semiconductor region) 24A is formed on the second main surface of the n-type FZ wafer 2. Then, p-type impurity ions, such as boron ions, are implanted into the second main surface of the n-type FZ wafer 2 using the resist mask 41 as a mask. The ion implantation conditions for forming the first p⁺ diffusion separation layer 24A may be, for example, a dose of 5×10¹⁴ cm⁻² to 5×10¹⁵ cm⁻² and an acceleration energy of 30 KeV to 100 KeV. Then, etching is performed using the resist mask 41 to remove the screen oxide film 3-2 exposed from the opening of the resist mask 41.

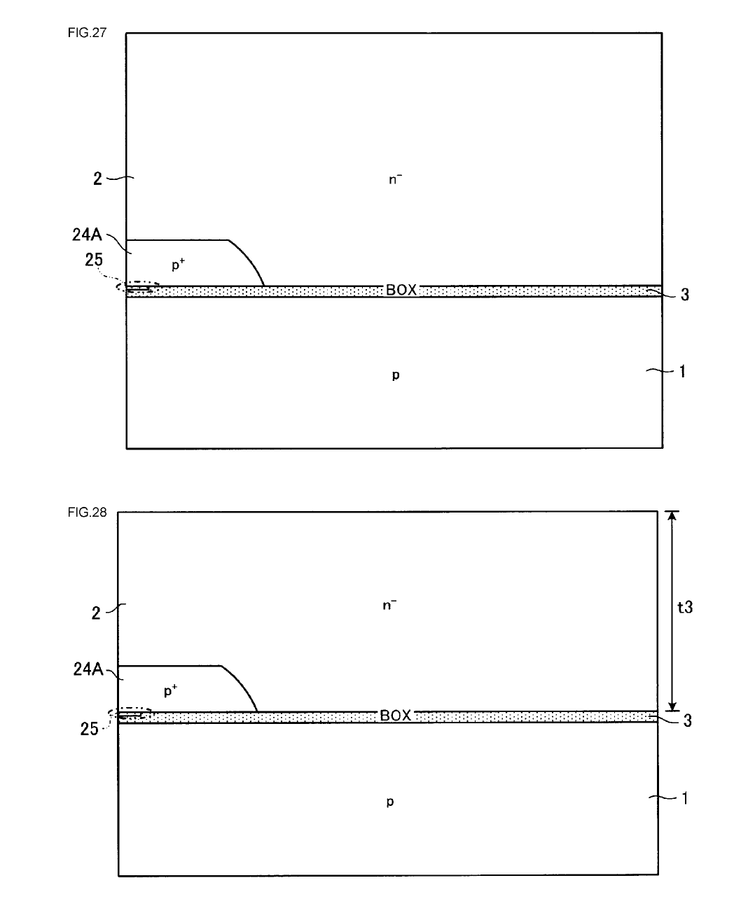

Then, the resist mask 41 is removed and the n-type FZ wafer 2 is cleaned. Then, a thermal annealing process is performed to form the first p⁺ diffusion separation layer 24A and the n-type FZ wafer 2 is cleaned. For example, the thermal annealing process for forming the first p⁺ diffusion separation layer 24A may be performed at a temperature of 900° C. for 30 minutes in a nitrogen (N) atmosphere. Then, as illustrated in FIG. 27, similarly to the first embodiment, the first main surface of the p-type CZ wafer 1 on which the silicon oxide film 3-1 is formed is bonded to the second main surface of the n-type FZ wafer 2 on which the screen oxide film 3-2 is formed. In this way, a mark region 25 is formed in a portion of the p-type CZ wafer 1 from which the silicon oxide film 3-1 is removed.

Then, similarly to the first embodiment, the thermal annealing process is performed for an SOI wafer obtained by bonding the n-type FZ wafer 2 and the p-type CZ wafer 1. In this way, the bonding between the n-type FZ wafer 2 and the p-type CZ wafer 1 is strengthened. In addition, the first p⁺ diffusion separation layer 24A is thermally diffused by the thermal annealing process for bonding the p-type CZ wafer 1 and the n-type FZ wafer 2. Then, as illustrated in FIG. 28, the SOI wafer obtained by bonding the p-type CZ wafer 1 and the n-type FZ wafer 2 is polished from the main surface (hereinafter, simply referred to as the first main surface of the n-type FZ wafer 2) on the side of the n-type FZ wafer 2 until the n-type FZ wafer 2 has a predetermined thickness t3. For example, the thickness t3 of the n-type FZ wafer 2 may be 68 μm. In this way, the SOI wafer in which the p-type CZ wafer 1, the silicon oxide film 3, and the n-type FZ wafer 2 are laminated is completed.

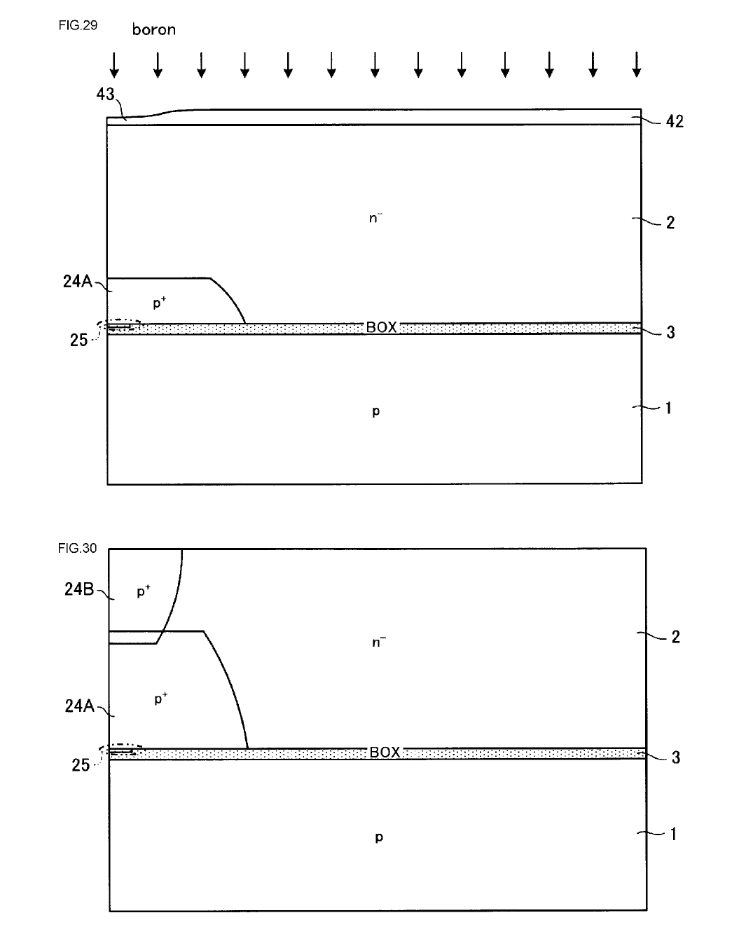

Then, as illustrated in FIG. 29, a thermally oxidized film 42 is formed on the first main surface of the n-type FZ wafer 2. The thickness of the thermally oxidized film 42 may be in the range of, for example, 600 nm to 1000 nm. Then, a resist mask (not illustrated) in which a portion corresponding to the first p⁺ diffusion separation layer 24A is opened is formed on the first main surface of the n-type FZ wafer 2 by photolithography. The portion corresponding to the first p⁺ diffusion separation layer 24A is a portion of the first main surface of the n-type FZ wafer 2 which is opposite to a portion of the second main surface of the n-type FZ wafer 2 in which the first p⁺ diffusion separation layer 24A is formed. When the resist mask is formed, the mark region 25 functions as a positioning mark.

Then, the thermally oxidized film 42 is selectively removed using the resist mask formed on the first main surface of the n-type FZ wafer 2 as a mask and the SOI wafer is cleaned. Then, a thermal oxidation process is performed to form a screen oxide film 43 on the first main surface of the n-type FZ wafer 2. In this way, the screen oxide film 43 is formed in a portion of the first main surface of the n-type FZ wafer 2 in which the thermally oxidized film 42 is not provided. The thickness of the screen oxide film 43 is, for example, 30 nm. Then, the resist mask formed on the first main surface of the n-type FZ wafer 2 is removed.

Then, boron ions are implanted into the first main surface of the n-type FZ wafer 2 through the screen oxide film 43 in order to form the second p⁺ diffusion separation layer 24B. In this case, since the thickness of the thermally oxidized film 42 is so large that impurity ions may not be implanted, boron ions are not implanted into a portion of the first main surface of the n-type FZ wafer 2 in which the thermally oxidized film 42 is formed. The ion implantation conditions for forming the second p⁺ diffusion separation layer 24B may be, for example, a dose of 5×10¹⁴ cm⁻² to 5×10¹⁵ cm⁻² and an acceleration energy of 30 KeV to 60 KeV. Then, the SOI wafer is cleaned.

Then, the first p⁺ diffusion separation layer 24A formed in the surface layer of the second main surface of the n-type FZ wafer 2 and the second p⁺ diffusion separation layer 24B formed in the surface layer of the first main surface of the n-type FZ wafer 2 are thermally diffused by the thermal annealing process and are connected to each other. For example, the thermal annealing process for connecting the first p⁺ diffusion separation layer 24A and the second p⁺ diffusion separation layer 24B may be performed at a temperature of 1300° C. for 14 hours to 20 hours in a nitrogen (N) atmosphere or an argon atmosphere. In this way, as illustrated in FIG. 30, the second p⁺ diffusion separation layer 24B which comes into contact with the first p⁺ diffusion separation layer 24A is formed in the first main surface of the n-type FZ wafer 2 at a position corresponding to the first p⁺ diffusion separation layer 24A. Then, the thermally oxidized film 42 and the screen oxide film 43 are all removed.

As illustrated in FIG. 31, a surface element structure of the RB-IGBT, a structure for maintaining the breakdown voltage of the RB-IGBT, and a structure for maintaining the reverse breakdown voltage of the RB-IGBT are provided on the first main surface of the n-type FZ wafer 2. Then, similarly to the first embodiment, a passivation film (not illustrated), such as a polyimide film or a nitride film, is formed on the entire first main surface of the n-type FZ wafer 2 on which, for example, the surface element structure is formed. Then, the passivation film is etched such that the electrode region of the surface element structure is exposed and an electrode pad region is formed. After the surface element structure is formed, light ion irradiation and thermal annealing for adjusting a lifetime are performed, if necessary.

Then, the entire first main surface of the n-type FZ wafer 2 on which, for example, the surface element structure is formed is protected by a protective resist and a BG tape is attached to the first main surface of the n-type FZ wafer 2 with the protective resist interposed therebetween. Then, similarly to the first embodiment, the subsequent process is performed to form grooves for making the thickness of the active region less than that of the termination structure, the p collector region 11, and the collector electrode 12 on the second main surface of the p-type CZ wafer and the wafer is diced into individual. In this way, the RB-IGBT illustrated in FIG. 23 is completed.

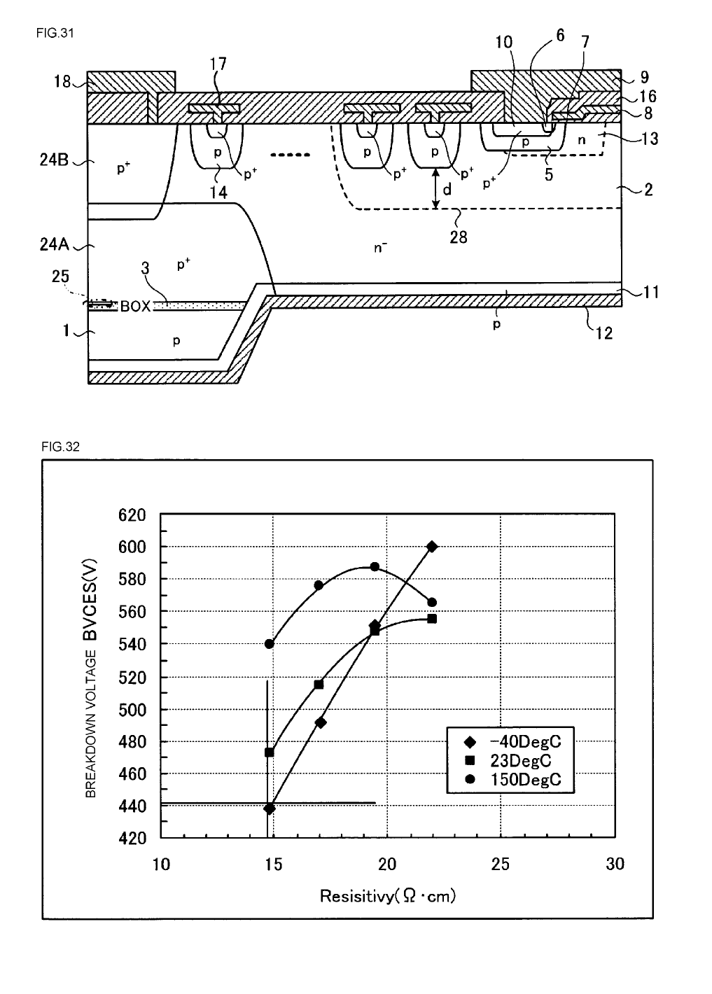

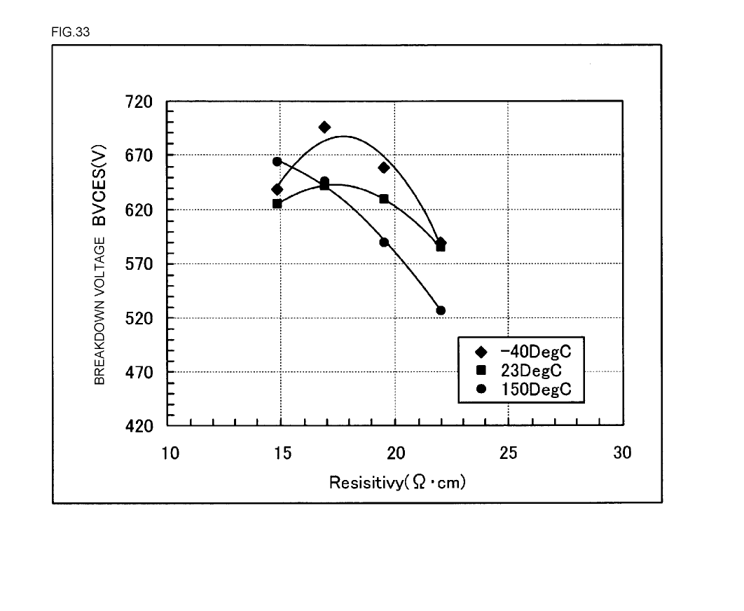

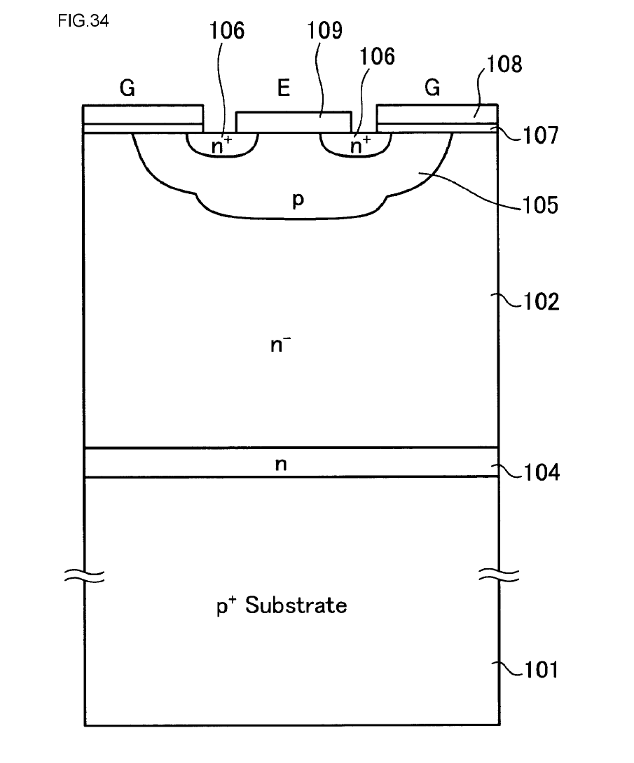

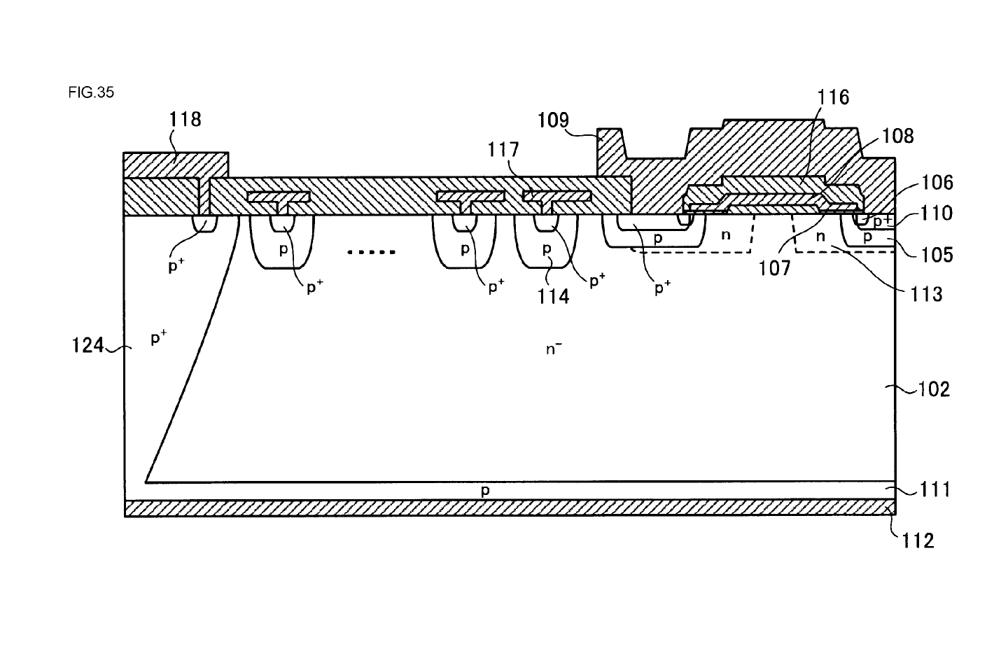

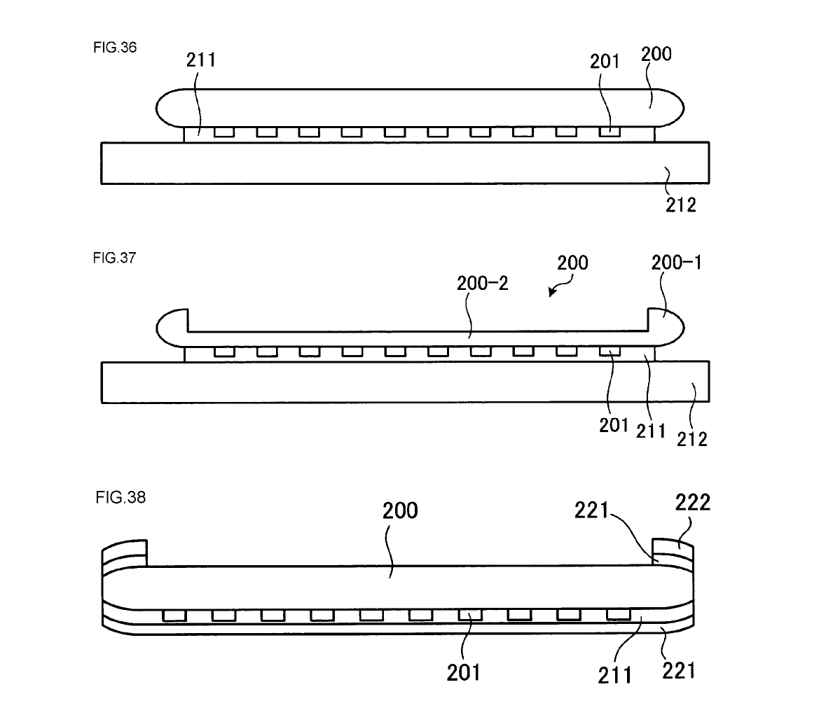

Next, the electric characteristics of the RB-IGBT illustrated in FIG. 23 will be described. FIGS. 32 and 33 are characteristic diagrams illustrating the breakdown voltage characteristics of the semiconductor device according to the third embodiment. In order to reduce a reverse leakage current when the RB-IGBT is used at a high temperature, the distance d of a depletion layer region which is spread to the n⁻ drift region 2 when a guaranteed reverse bias voltage VECS is applied in the second depth direction from a boundary surface 28 to the p base region 5 or the field limiting ring 14 needs to be larger than the diffusion length of the minor carrier in the n⁻ drift region 2 (see FIG. 31). The guaranteed reverse bias voltage VECS is 400 V in the case of an element with a breakdown voltage class of 400 V.

Therefore, the base width of a pnp bipolar transistor which includes a p emitter including the p base region 5 or the field limiting ring 14, an n base, which is a portion of the n⁻ drift region 2 that is not depleted, and a p collector including the p collector region 11, the first p⁺ diffusion separation layer 24A, and the second p⁺ diffusion separation layer 24B is ensured as a predetermined value and a current amplification coefficient is reduced. A base current which is generated in order to recombine an electron current generated due to the generation of carriers or the recombination of the carriers in the depletion layer region needs not to be excessively amplified.

In the semiconductor device according to the third embodiment, the thickness T_{SUB} of the n-type semiconductor substrate which will be the n⁻ drift region 2 is 65 μm, the p collector region 11 has the impurity concentration distribution illustrated in FIG. 18, and the distance d is 10 μm. In addition, electron beam irradiation is performed under the conditions of 40 Kgry and 5.4 MeV and an annealing process is performed at a temperature of 330° C. to 350° C. for 40 minutes to 80 minutes in a hydrogen atmosphere. FIG. 32 illustrates the relation between the forward breakdown voltage BVCES of the semiconductor device according to the third embodiment and the resistivity of the n⁻ drift region 2 in this case. In addition, FIG. 33 illustrates the relation between the reverse breakdown voltage BVCES of the semiconductor device according to the third embodiment and the resistivity of the n⁻ drift region 2.

When a variation in the resistivity of the n⁻ drift region 2 is in the range of −8% to +8%, a variation in the thickness of the n⁻ drift region 2 is in the range of −3% to +3%, and the breakdown voltage of the element is guaranteed in the temperature range of −40° C. to 150° C., the average resistivity of the n-type semiconductor substrate which will be the n⁻ drift region 2 is 17 Ω·cm and the average thickness of the n-type semiconductor substrate which will be the n⁻ drift region 2 is 68 μm. In this case, it is possible to obtain a high breakdown voltage in an RB-IGBT with a desired breakdown voltage class, for example, a breakdown voltage class of 400 V. In the temperature range of −40° C. to 150° C. in which the breakdown voltage of the element is guaranteed, the electric characteristics of the semiconductor device according to the third embodiment need to be guaranteed when the semiconductor device is used in, for example, electric vehicles.

As described above, according to the semiconductor device of the third embodiment, in the RB-IGBT having a structure for maintaining the reverse breakdown voltage, it is possible to obtain the same effect as that obtained by the semiconductor device according to the first embodiment. In addition, according to the semiconductor device of the third embodiment, the first p⁺ diffusion separation layer 24A is formed before, for example, the surface element structure 20 of the element is formed. Therefore, it is possible to reduce the thermal diffusion time required to form the p-type isolation region which passes through the n⁻ drift region 2 forming the structure for maintaining the reverse breakdown voltage. In this way, it is possible to reduce crystal defects due to thermal diffusion which is performed at a high temperature for a long time.

### Fourth Embodiment

A semiconductor device according to a fourth embodiment will be described. The semiconductor device according to the fourth embodiment differs from that according to the third embodiment in that an IGBT having a surface element structure of a trench structure is formed.

In the semiconductor device according to the fourth embodiment, the surface element structure in an active region is the same as the surface element structure in the active region in the semiconductor device according to the second embodiment. The semiconductor device according to the fourth embodiment is similar to the semiconductor device according to the third embodiment except for the surface element structure.

A process of forming the surface element structure in the active region in the semiconductor device according to the fourth embodiment is the same as the process of forming the surface element structure in the active region in the semiconductor device according to the second embodiment. A method of manufacturing the semiconductor device according to the fourth embodiment is similar to the method of manufacturing the semiconductor device according to the third embodiment except for the process of forming the surface element structure in the active region.

As described above, according to the semiconductor device of the fourth embodiment, it is possible to obtain the same effect as that obtained by the semiconductor devices according to the first to third embodiments.

The invention is not limited to the above-described embodiments, but can be applied to semiconductor devices in which an element structure is formed using a thin wafer which will be an n⁻ drift region. In addition, in the above-described embodiments, the first conduction type is a p type and the second conduction type is an n type. However, in other embodiments of the invention, the first conduction type may be an n type and the second conduction type may be a p type. In this case, the same effect as described above is obtained.

As described above, the semiconductor devices and the semiconductor device manufacturing methods according to embodiments of the invention are effective in a semiconductor device with a low breakdown voltage which is formed on a thin wafer. Specifically, for example, the semiconductor devices and the semiconductor device manufacturing methods according to the invention are useful for improving the efficiency of semiconductor devices with a low breakdown voltage equal to or less than 600 V which are used in pulsed power supplies for PDPs or strobes and industrial power converters with an AC input voltage of 200 V. In addition, the semiconductor devices and the semiconductor device manufacturing methods according to embodiments of the invention are useful for improving the efficiency of inverters which drive motors in electric vehicles.

A list and description of reference numerals and symbols used herein are as noted below:
1 p-type region (p-type CZ wafer)
2 n⁻ drift region (n-type FZ wafer)
3 silicon oxide film
4 n field stop region
5 p base region
6 n⁺ emitter region
7 gate insulating film
8 gate electrode
9 emitter electrode
10 p⁺ base contact region
11 p collector region
12 collector electrode
13 n hole barrier region
14 field limiting ring
15 n⁺ region
16 interlayer insulating film
17 field plate region
18 field plate
26 termination structure
27 active region
t11 thickness of n field stop region in active region
t12 thickness of n field stop region in termination structure

Although a few embodiments have been shown and described, it would be appreciated by those skilled in the art that changes may be made in these embodiments without departing from the principles and spirit of the invention, the scope of which is defined in the claims and their equivalents.

What is claimed is:

1. A semiconductor device comprising:
a first semiconductor region of a first conduction type;
a second semiconductor region which is of a second conduction type and comes into contact with one surface of the first semiconductor region;
a third semiconductor region which is of the second conduction type, comes into contact with a surface of the second semiconductor region opposite to the first semiconductor region, and has a resistivity higher than that of the second semiconductor region;
a fourth semiconductor region which is of the first conduction type and is selectively provided in a surface layer of the third semiconductor region opposite to the second semiconductor region;
a fifth semiconductor region which is of the second conduction type, is provided in the fourth semiconductor region, and has a resistivity lower than that of the third semiconductor region;
a gate electrode which is formed on a surface of the fourth semiconductor region interposed between the third semiconductor region and the fifth semiconductor region, with a gate insulating film interposed therebetween;
a first electrode which electrically connects the fourth semiconductor region and the fifth semiconductor region;
a second electrode which comes into contact with the other surface of the first semiconductor region;
an active region which is formed by at least the first semiconductor region, the second semiconductor region, and the third semiconductor region and is provided in the inner circumference of a chip which is thinner than the outer circumference of the chip;
a termination structure which is provided closer to the outer circumference of the chip than the active region; and
an insulating region which is selectively provided in the termination structure and is disposed substantially at the same position as that of the second electrode in a first depth direction from the surface of the third semiconductor region opposite to the second semiconductor region to the second semiconductor region.

2. The semiconductor device according to claim 1, further comprising:
a sixth semiconductor region which is of the second conduction type, is selectively provided in a surface layer of the third semiconductor region opposite to the second semiconductor region, and covers a surface of the fourth semiconductor region close to the second semiconductor region,
wherein the gate electrode is provided on the surfaces of the third semiconductor region, the sixth semiconductor region, the fourth semiconductor region, and the fifth semiconductor region, with the gate insulating film interposed therebetween.

3. The semiconductor device according to claim 1, wherein
the first semiconductor region and the second electrode are provided so as to extend from the active region to the termination structure, and
the position of the insulating region from the surface of the third semiconductor region opposite to the second semiconductor region in the first depth direction is substantially the same as the position of the second electrode from the surface of the third semiconductor region opposite to the second semiconductor region in the first depth direction in the active region.

4. The semiconductor device according to claim 1, wherein
the second semiconductor region is provided so as to extend from the active region to the termination structure, and
the depth of the second semiconductor region in the first depth direction in the active region is less than the depth of the second semiconductor region in the first depth direction in the termination structure.

5. The semiconductor device according to claim 1, wherein
the depth of the second semiconductor region in the first depth direction in the active region is equal to or greater than 1.5 μm.

6. The semiconductor device according to claim 1, wherein
the thickness of the outer circumference of the chip in which the termination structure is provided is greater than 80 μm.

7. The semiconductor device according to claim 1, wherein the termination structure includes:
a plurality of seventh semiconductor regions which are of the first conduction type and are selectively provided in the surface layer of the third semiconductor region opposite to the second semiconductor region;
a plurality of field plate regions which are electrically connected to the plurality of seventh semiconductor regions, respectively;
an eighth semiconductor region which is of the second conduction type, is selectively provided in a portion of the surface layer of the third semiconductor region which is opposite to the second semiconductor region and is closer to the outer circumference of the chip than the seventh semiconductor region so as to be separated from the seventh semiconductor region, and has a resistivity less than that of the third semiconductor region; and
a field plate which comes into contact with the eighth semiconductor region.

8. The semiconductor device according to claim 7, wherein the field plate region is made of polysilicon.

9. A semiconductor device comprising:
a first semiconductor region of a first conduction type;
a second semiconductor region which is a second conduction type and comes into contact with one surface of the first semiconductor region;
a third semiconductor region which is the second conduction type, comes into contact with a surface of the second semiconductor region opposite to the first semiconductor region, and has a resistivity higher than that of the second semiconductor region;
a fourth semiconductor region which is the first conduction type and is selectively provided in a surface layer of the third semiconductor region opposite to the second semiconductor region;
a trench which reaches the third semiconductor region through the fourth semiconductor region;
a gate insulating film which is provided along a side wall and a bottom of the trench;
a gate electrode which is buried in the gate insulating film;
a fifth semiconductor region which is the second conduction type, is provided in the fourth semiconductor region so as to come into contact with the gate insulating film on the side wall of the trench, and has a resistivity lower than that of the third semiconductor region;
a first electrode which electrically connects the fourth semiconductor region and the fifth semiconductor region;
a second electrode which comes into contact with the other surface of the first semiconductor region;
an active region which is formed by at least the first semiconductor region, the second semiconductor region, and the third semiconductor region and is provided in the inner circumference of a chip which is thinner than the outer circumference of the chip;
a termination structure which is provided closer to the outer circumference of the chip than the active region; and
an insulating region which is selectively provided in the termination structure and is disposed substantially at the same position as that of the second electrode in a first depth direction from the surface of the third semiconductor region opposite to the second semiconductor region to the second semiconductor region.

10. The semiconductor device according to claim 9,
wherein the first semiconductor region and the second electrode are provided so as to extend from the active region to the termination structure, and
the position of the insulating region from the surface of the third semiconductor region opposite to the second semiconductor region in the first depth direction is substantially the same as the position of the second electrode from the surface of the third semiconductor region opposite to the second semiconductor region in the first depth direction in the active region.

11. The semiconductor device according to claim 9,
wherein the second semiconductor region is provided so as to extend from the active region to the termination structure, and
the depth of the second semiconductor region in the first depth direction in the active region is less than the depth of the second semiconductor region in the first depth direction in the termination structure.

12. The semiconductor device according to claim 9,
wherein the depth of the second semiconductor region in the first depth direction in the active region is equal to or greater than 1.5 μm.

13. The semiconductor device according to claim 9,
wherein the thickness of the outer circumference of the chip in which the termination structure is provided is greater than 80 μm.

14. The semiconductor device according to claim 9,
wherein the termination structure includes:
a plurality of seventh semiconductor regions which are of the first conduction type and are selectively provided in the surface layer of the third semiconductor region opposite to the second semiconductor region;
a plurality of field plate regions which are electrically connected to the plurality of seventh semiconductor regions, respectively;
an eighth semiconductor region which is of the second conduction type, is selectively provided in a portion of the surface layer of the third semiconductor region which is opposite to the second semiconductor region and is closer to the outer circumference of the chip than the seventh semiconductor region so as to be separated from the seventh semiconductor region, and has a resistivity less than that of the third semiconductor region; and
a field plate which comes into contact with the eighth semiconductor region.

15. The semiconductor device according to claim 14, wherein the field plate region is made of polysilicon.

16. A semiconductor device comprising:
a first semiconductor region of a first conduction type;
a third semiconductor region which is of a second conduction type and comes into contact with one surface of the first semiconductor region;
a fourth semiconductor region which is of the first conduction type and is selectively provided in a surface layer of the third semiconductor region opposite to the first semiconductor region;
a fifth semiconductor region which is of the second conduction type, is provided in the fourth semiconductor region, and has a resistivity lower than that of the third semiconductor region;
a gate electrode which is formed on a surface of the fourth semiconductor region interposed between the third semiconductor region and the fifth semiconductor region, with a gate insulating film interposed therebetween;
a first electrode which electrically connects the fourth semiconductor region and the fifth semiconductor region;
a second electrode which comes into contact with the other surface of the first semiconductor region;
an active region which is formed by at least the first semiconductor region and the third semiconductor region and is provided in the inner circumference of a chip which is thinner than the outer circumference of the chip;
a termination structure which is provided closer to the outer circumference of the chip than the active region; and
an insulating region which is selectively provided in the termination structure and is disposed substantially at the same position as that of the second electrode in a first depth direction from the surface of the third semiconductor region opposite to the first semiconductor region to the first semiconductor region.

17. The semiconductor device according to claim 16, further comprising:
a sixth semiconductor region which is of the second conduction type, is selectively provided in a surface layer of the third semiconductor region opposite to the first semiconductor region, and covers a surface of the fourth semiconductor region close to the first semiconductor region,
wherein the gate electrode is provided on the surfaces of the third semiconductor region, the sixth semiconductor region, the fourth semiconductor region, and the fifth semiconductor region, with the gate insulating film interposed therebetween.

18. The semiconductor device according to claim 16, wherein
the first semiconductor region and the second electrode are provided so as to extend from the active region to the termination structure, and
the position of the insulating region from the surface of the third semiconductor region opposite to the first semiconductor region in the first depth direction is substantially the same as the position of the second electrode from the surface of the third semiconductor region opposite to the first semiconductor region in the first depth direction in the active region.

19. The semiconductor device according to claim 16, further comprising:
a ninth semiconductor region which is of the first conduction type and is provided in the third semiconductor region so as to be deeper than the first semiconductor region in a second depth direction from the other surface of the first semiconductor region to the third semiconductor region and to overlap the insulating region.

20. The semiconductor device according to claim 16,
wherein the thickness of the outer circumference of the chip in which the termination structure is provided is greater than 80 μm.

21. The semiconductor device according to claim 16,
wherein the termination structure includes:
a plurality of seventh semiconductor regions which are of the first conduction type and are selectively provided in the surface layer of the third semiconductor region opposite to the second semiconductor region;
a plurality of field plate regions which are electrically connected to the plurality of seventh semiconductor regions, respectively;
a tenth semiconductor region which is of the first conduction type, is selectively provided in a portion of the surface layer of the third semiconductor region which is opposite to the first semiconductor region and is closer to the outer circumference of the chip than the seventh semiconductor region so as to be separated from the seventh semiconductor region, and comes into contact with the ninth semiconductor region; and
a field plate which comes into contact with the tenth semiconductor region.

22. The semiconductor device according to claim 21, wherein the field plate region is made of polysilicon.

23. A semiconductor device comprising:
a first semiconductor region of a first conduction type;
a third semiconductor region which is a second conduction type and comes into contact with one surface of the first semiconductor region;
a fourth semiconductor region which is the first conduction type and is selectively provided in a surface layer of the third semiconductor region opposite to the first semiconductor region;
a trench which reaches the third semiconductor region through the fourth semiconductor region;
a gate insulating film which is provided along a side wall and a bottom of the trench;
a gate electrode which is buried in the gate insulating film;
a fifth semiconductor region which is the second conduction type, is provided in the fourth semiconductor region so as to come into contact with the gate insulating film on the side wall of the trench, and has a resistivity lower than that of the third semiconductor region;
a first electrode which electrically connects the fourth semiconductor region and the fifth semiconductor region;
a second electrode which comes into contact with the other surface of the first semiconductor region;
an active region which is formed by at least the first semiconductor region and the third semiconductor region and is provided in the inner circumference of a chip which is thinner than the outer circumference of the chip;
a termination structure which is provided closer to the outer circumference of the chip than the active region; and
an insulating region which is selectively provided in the termination structure and is disposed substantially at the same position as that of the second electrode in a first depth direction from the surface of the third semiconductor region opposite to the first semiconductor region to the first semiconductor region.

24. The semiconductor device according to claim 23,
wherein the first semiconductor region and the second electrode are provided so as to extend from the active region to the termination structure, and
the position of the insulating region from the surface of the third semiconductor region opposite to the first semiconductor region in the first depth direction is substantially the same as the position of the second electrode from the surface of the third semiconductor region opposite to the first semiconductor region in the first depth direction in the active region.

25. The semiconductor device according to claim 23, further comprising:
a ninth semiconductor region which is of the first conduction type and is provided in the third semiconductor region so as to be deeper than the first semiconductor region in a second depth direction from the other surface of the first semiconductor region to the third semiconductor region and to overlap the insulating region.

26. The semiconductor device according to claim 23,
wherein the thickness of the outer circumference of the chip in which the termination structure is provided is greater than 80 μm.

27. The semiconductor device according to claim 23,
wherein the termination structure includes:
a plurality of seventh semiconductor regions which are of the first conduction type and are selectively provided in the surface layer of the third semiconductor region opposite to the second semiconductor region;
a plurality of field plate regions which are electrically connected to the plurality of seventh semiconductor regions, respectively;
a tenth semiconductor region which is of the first conduction type, is selectively provided in a portion of the surface layer of the third semiconductor region which is opposite to the first semiconductor region and is closer to the outer circumference of the chip than the seventh semiconductor region so as to be separated from the seventh semiconductor region, and comes into contact with the ninth semiconductor region; and
a field plate which comes into contact with the tenth semiconductor region.

28. The semiconductor device according to claim 27, wherein the field plate region is made of polysilicon.

29. A method of manufacturing a semiconductor device including an active region which is provided in the inner circumference of a chip thinner than the outer circumference of the chip, comprising:
forming an insulating region on a main surface of a first wafer which is of a first conduction type;
forming a second-conduction-type semiconductor region in a surface layer of a main surface of a second wafer which is of a second conduction type;
bonding the surface of the first wafer on which the insulating region is formed and the surface of the second wafer on which the second-conduction-type semiconductor region is formed; and
combining the bonded first and second wafers using a heat treatment.

30. A method of manufacturing a semiconductor device including an active region which is provided in the inner circumference of a chip thinner than the outer circumference of the chip, comprising:
forming an insulating region on a main surface of a first wafer which is of a first conduction type;
forming a first-conduction-type semiconductor region in a surface layer of a main surface of a second wafer which is of a second conduction type on an outer circumferential side of the chip;
bonding the surface of the first wafer on which the insulating region is formed and the surface of the second wafer on which the first-conduction-type semiconductor region is formed; and
combining the bonded first and second wafers using a heat treatment.

31. The method of manufacturing the semiconductor device according to claim 29, further comprising:
forming a surface element structure in the active region of the main surface, which is opposite to the first wafer, of the second wafer combined with the first wafer.

32. The method of manufacturing the semiconductor device according to claim 30, further comprising:
forming a surface element structure in the active region of the main surface, which is opposite to the first wafer, of the second wafer combined with the first wafer.

33. The method of manufacturing the semiconductor device according to claim 31, further comprising:
performing wet etching to selectively remove a portion corresponding to the surface element structure in the first wafer combined with the second wafer.
